(19) United States
(12) Patent Application Publication
(10) Pub. No.: US 2024/0290694 A1
(43) Pub. Date: Aug. 29, 2024

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventor: Ryotaro KAKIZAKI, Kyoto-shi (JP)

(21) Appl. No.: 18/651,155

(22) Filed: Apr. 30, 2024

Related U.S. Application Data
(63) Continuation of application No. PCT/JP2022/043313, filed on Nov. 24, 2022.

(30) Foreign Application Priority Data
Dec. 1, 2021 (JP) 2021-195175

(51) Int. Cl. H01L 23/495; H01L 21/48; H01L 23/00; H01L 23/31

(52) U.S. Cl. CPC H01L 23/49513; H01L 21/4825; H01L 21/4842; H01L 23/3121; H01L 23/49555; H01L 24/29; H01L 24/32; H01L 24/06; H01L 24/45; H01L 24/46; H01L 24/48; H01L 24/49; H01L 24/73; H01L 2224/0603; H01L 2224/06051; H01L 2224/06181; H01L 2224/29139; H01L 2224/32245; H01L 2224/45124; H01L 2224/45144; H01L 2224/45147; H01L 2224/46; H01L 2224/48091; H01L 2224/48245; H01L 2224/49052; H01L 2224/49112; H01L 2224/73265; H01L 2924/10253; H01L 2924/10272; H01L 2924/13055; H01L 2924/13091

(57) ABSTRACT

A semiconductor device includes a semiconductor element, a first lead including a die pad portion and a first terminal portion, and a sealing resin. A first-lead reverse surface is exposed from a second resin surface. The first terminal portion includes a first section joined to the die pad portion, a second section located on a first side in a z direction with respect to the first section and used for mounting, and a third section between the first section and the second section.

### TECHNICAL FIELD

The present disclosure relates to a semiconductor device and a method for manufacturing a semiconductor device.

### BACKGROUND ART

JP-A-2017-174951 discloses an example of a semiconductor device that includes: a first lead including a first pad having a pad obverse surface and a pad reverse surface; a second lead, a third lead, a semiconductor element mounted on the pad obverse surface, and a sealing resin in contact with the pad obverse surface and covering the semiconductor element. The first lead, the second lead, and the third lead respectively have a first terminal, a second terminal, and a third terminal extending in the same direction. The semiconductor device is mounted onto a circuit board or the like by inserting the first terminal, the second terminal, and the third terminal into through holes formed in the circuit board. When the semiconductor device is attached to a heat sink, an insulating sheet or the like is disposed between the pad reverse surface and the heat sink.

### BRIEF DESCRIPTION OF THE DRAWINGS

FIG. 1 is a perspective view of a semiconductor device according to a first embodiment of the present disclosure.

FIG. 2 is a perspective view of the semiconductor device according to the first embodiment of the present disclosure.

FIG. 3 is a perspective view of the semiconductor device according to the first embodiment of the present disclosure.

FIG. 4 is a perspective view showing relevant portions of the semiconductor device according to the first embodiment of the present disclosure.

FIG. 5 is a perspective view showing relevant portions of the semiconductor device according to the first embodiment of the present disclosure.

FIG. 6 is a plan view of the semiconductor device according to the first embodiment of the present disclosure.

FIG. 7 is a bottom view of the semiconductor device according to the first embodiment of the present disclosure.

FIG. 8 is a front view of the semiconductor device according to the first embodiment of the present disclosure.

FIG. 9 is a side view of the semiconductor device according to the first embodiment of the present disclosure.

FIG. 10 is a plan view showing relevant portions of the semiconductor device according to the first embodiment of the present disclosure.

FIG. 11 is a bottom view showing relevant portions of the semiconductor device according to the first embodiment of the present disclosure.

FIG. 12 is a sectional view taken along line XII-XII of FIG. 11.

FIG. 13 is a sectional view taken along line XIII-XIII of FIG. 11.

FIG. 14 is a sectional view taken along line XIV-XIV of FIG. 11.

FIG. 15 is a sectional view taken along line XV-XV of FIG. 11.

FIG. 16 is a sectional view showing the semiconductor device in a state of use according to the first embodiment of the present disclosure.

FIG. 17 is a flowchart of an example of a method for manufacturing a semiconductor device according to the first embodiment of the present disclosure.

FIG. 18 is a sectional view showing a step of the method for manufacturing a semiconductor device according to the first embodiment of the present disclosure.

FIG. 19 is a sectional view showing a step of the method for manufacturing a semiconductor device according to the first embodiment of the present disclosure.

FIG. 20 is a sectional view showing a step of the method for manufacturing a semiconductor device according to the first embodiment of the present disclosure.

FIG. 21 is a sectional view showing a step of the method for manufacturing a semiconductor device according to the first embodiment of the present disclosure.

FIG. 22 is a sectional view showing a step of the method for manufacturing a semiconductor device according to the first embodiment of the present disclosure.

FIG. 23 is a sectional view showing a semiconductor device according to a first variation of the first embodiment of the present disclosure.

FIG. 24 is a sectional view showing the semiconductor device in a state of use according to the first variation of the first embodiment of the present disclosure.

FIG. 25 is a perspective view showing a semiconductor device according to a second variation of the first embodiment of the present disclosure.

FIG. 26 is a sectional view showing the semiconductor device according to the second variation of the first embodiment of the present disclosure.

FIG. 27 is a perspective view showing a semiconductor device according to a third variation of the first embodiment of the present disclosure.

FIG. 28 is a sectional view showing the semiconductor device according to the third variation of the first embodiment of the present disclosure.

FIG. 29 is a perspective view showing a semiconductor device according to a fourth variation of the first embodiment of the present disclosure.

FIG. 30 is a sectional view showing the semiconductor device according to the fourth variation of the first embodiment of the present disclosure.

FIG. 31 is a sectional view showing a semiconductor device according to a fifth variation of the first embodiment of the present disclosure.

FIG. 32 is a sectional view showing a semiconductor device according to a sixth variation of the first embodiment of the present disclosure.

FIG. 33 is a sectional view showing a semiconductor device according to a seventh variation of the first embodiment of the present disclosure.

FIG. 34 is an enlarged view of FIG. 33.

FIG. 35 is a sectional view showing a semiconductor device according to an eighth variation of the first embodiment of the present disclosure.

FIG. 36 is a plan view showing relevant portions of a semiconductor device according to a second embodiment of the present disclosure.

FIG. 37 is a sectional view showing relevant portions of the semiconductor device according to the second embodiment of the present disclosure.

FIG. 38 is a perspective view of the semiconductor device according to the third embodiment of the present disclosure.

FIG. 39 is a plan view showing relevant portions of the semiconductor device according to the third embodiment of the present disclosure.

FIG. 40 is a sectional view showing relevant portions of a semiconductor device according to a fourth embodiment of the present disclosure.

FIG. 41 is a sectional view showing a semiconductor device according to a fifth embodiment of the present disclosure.

FIG. 42 is a sectional view showing a semiconductor device according to a sixth embodiment of the present disclosure.

FIG. 43 is a sectional view showing a semiconductor device according to a first variation of the sixth embodiment of the present disclosure.

FIG. 44 is a sectional view showing a semiconductor device according to a second variation of the sixth embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, “third”, and so on are used merely as labels and not intended to order the items modified by the terms.

In the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”.

### First Embodiment

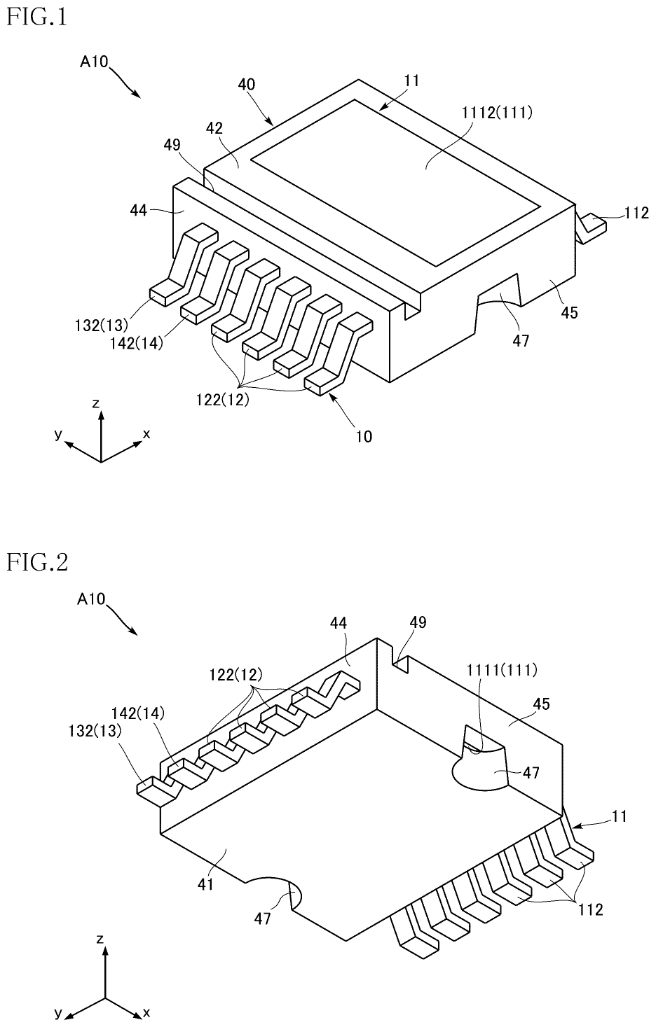

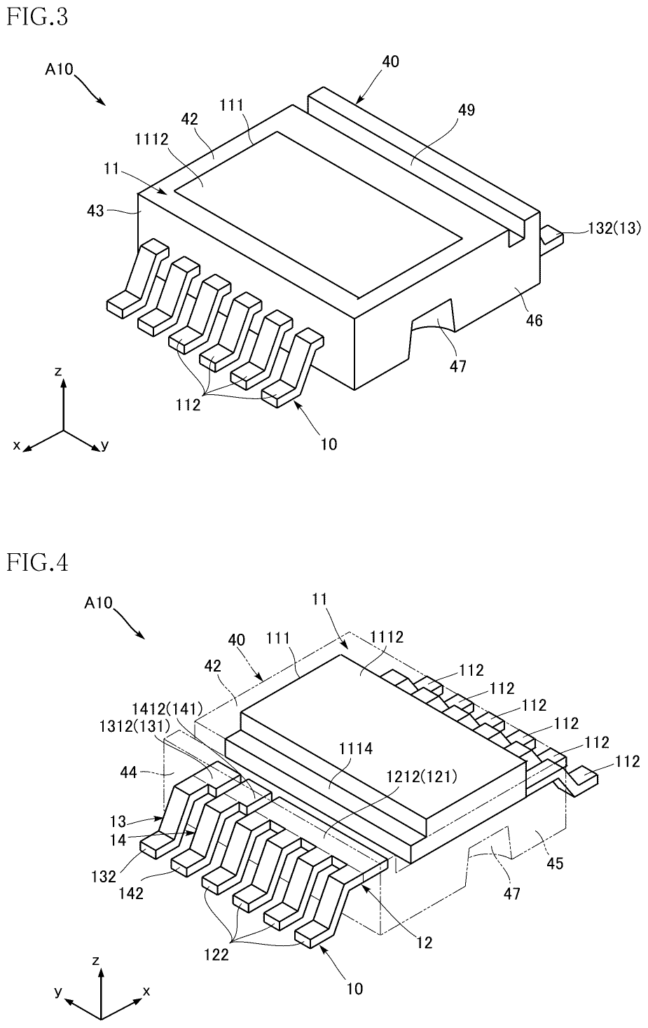

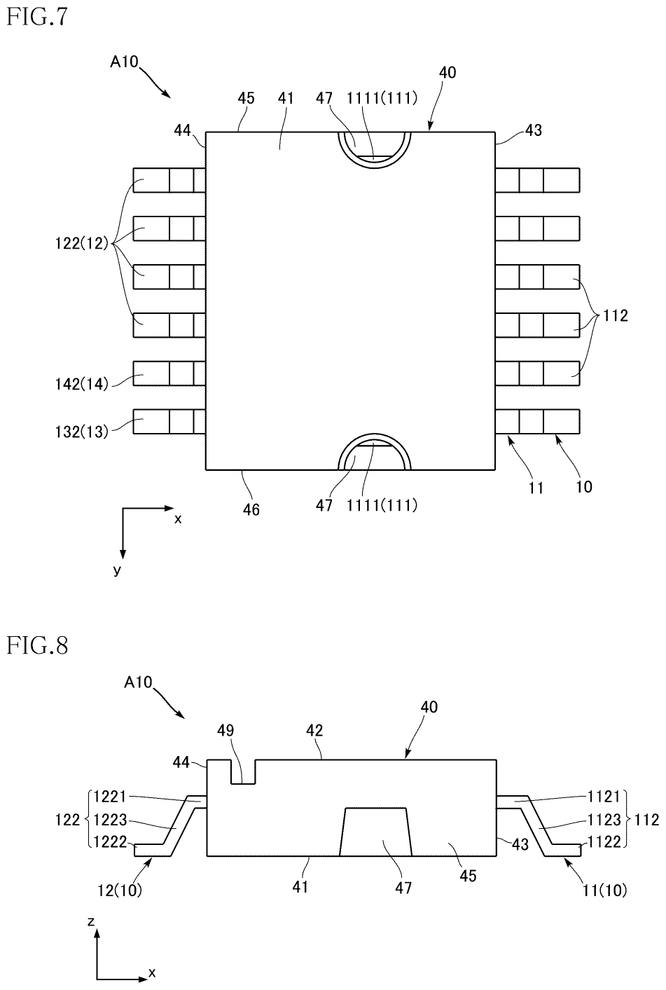

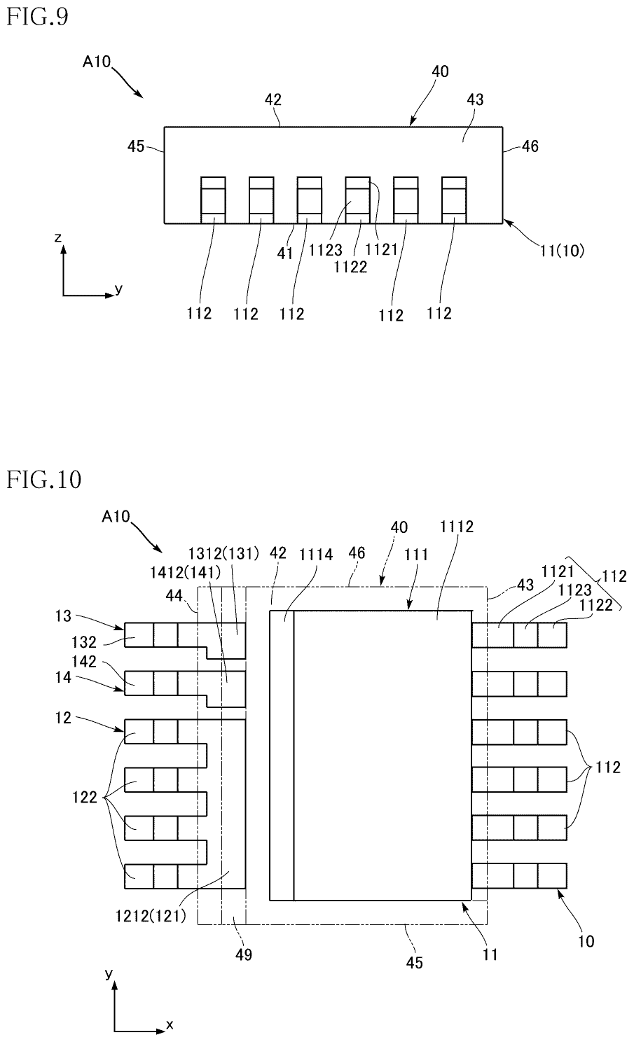

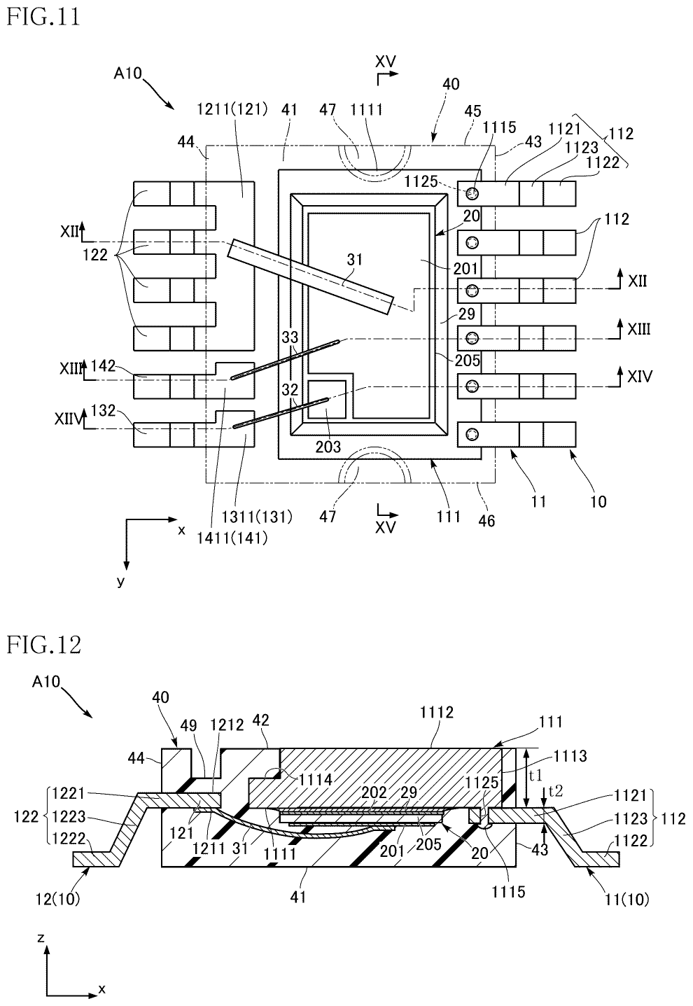

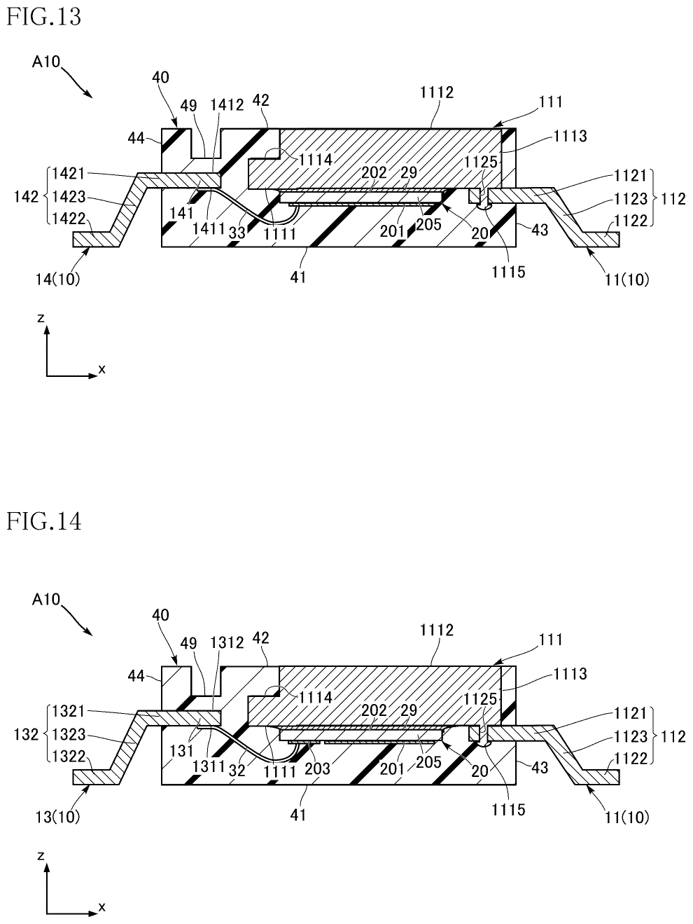

FIGS. 1 to 16 show a semiconductor device according to a first embodiment of the present disclosure. The semiconductor device A10 of the present embodiment includes a conductive member 10, a semiconductor element 20, connecting members 31, 32, and 33, and a sealing resin 40. In these figures, the z direction is an example of a thickness direction, and the x direction is an example of a first direction, and the y direction is an example of a second direction.

### Conductive Member 10

The conductive member 10 forms a conductive path to the semiconductor element 20. The conductive member 10 of the present embodiment includes a first lead 11, a second lead 12, a third lead 13, and a fourth lead 14. The first lead 11, the second lead 12, the third lead 13, and the fourth lead 14 are made of a suitable material, including but not limited to, copper (Cu) and a copper alloy, for example. In addition, the first lead 11, the second lead 12, the third lead 13, and the fourth lead 14 may have portions plated with silver (Ag), nickel (Ni), or tin (Sn), for example.

### First Lead 11

As shown in FIGS. 1 to 15, the first lead 11 includes a die pad portion 111 and a plurality of first terminal portions 112. The first lead 11 is fabricated by joining together the die pad portion 111 and the first terminal portions 112, which were separate components. The die pad portion 111 has a first-lead obverse surface 1111 and a first-lead reverse surface 1112. The first-lead obverse surface 1111 faces a first side in the z direction. The first-lead reverse surface 1112 faces a second side in the z direction. The first-lead obverse surface 1111 has the semiconductor element 20 mounted thereon.

The die pad portion 111 of the present embodiment additionally has a first-lead side surface 1113 and a first intermediate surface 1114. The first-lead side surface 1113 is located between the first-lead obverse surface 1111 and the first-lead reverse surface 1112 in the z direction, facing a first side in the x direction. The first intermediate surface 1114 is located between the first-lead obverse surface 1111 and the first-lead reverse surface 1112 in the z direction, facing the second side in the z direction (the same side that the first-lead reverse surface 1112 faces). In the present embodiment, the die pad portion 111 includes a plurality of engaging portions 1115 protruding from the first-lead obverse surface 1111 in the z direction and each received in an engaging hole 1125 (described later) in each first terminal portion 112. The engaging portions 1115 are arranged at equal intervals in the y direction.

The shape of the die pad portion 111 is not specifically limited. In the illustrated example, the die pad portion 111 is rectangular as viewed in the z direction. The shapes of the first-lead obverse surface 1111 and the first-lead reverse surface 1112 are not specifically limited either. In the illustrated example, the first-lead obverse surface 1111 and the first-lead reverse surface 1112 are rectangular as viewed in the z direction.

The first terminal portions 112 are arranged side by side in the y direction. Each first terminal portion 112 includes a first section 1121, a second section 1122, and a third section 1123.

The first sections 1121 are joined to the die pad portion 111. In the present embodiment, the first sections 1121 are joined to the first-lead obverse surface 1111 of the die pad portion 111. Each first section 1121 has an engaging hole 1125 extending therethrough in the z direction. The first section 1121 is swaged and joined to the die pad portion 111. More specifically, the first section 1121 is placed to receive the engaging portion 1115 of the die pad portion 111 in the engaging hole 1125. Then, while heat is applied, a die is pressed against the engaging portion 1115 from its tip. As a result, the tip of the engaging portion 1115 is deformed to abut against the engaging hole 1125. In addition, the circumferential surface of the engaging portion 1115 makes intimate contact with inner surface of the engaging hole 1125.

The first section 1121 extends toward the first side in the x direction. In the illustrated example, the first section 1121 extends parallel (or substantially parallel) to the x-y plane. The shape of the first section 1121 is not specifically limited. In the illustrated example, the first section 1121 is rectangular as viewed in the z direction. As shown in FIG. 12, the die pad portion 111 has a first length t1 in the z direction and the first section 1121 has a second length t2 in the z direction, where the first length t1 is greater than the second length t2. Although the respective lengths are not specifically limited, the first length t1 is at least three times and at most ten times the second length t2. That is, the first length t1 can be six times or more the second length t2. Note that forming the first lead 11 having such a length is difficult when the first lead 11 is formed as one piece from a material with step-sectioned-strips. The first section 1121 is spaced apart from the first-lead reverse surface 1112 in the z direction.

The second section 1122 is located on the first side in the z direction with respect to the first section 1121. The second section 1122 is used for surface mounting of the semiconductor device A10 onto a circuit board or the like. The second section 1122 extends in the x direction.

The third section 1123 is located between the first section 1121 and the second section 1122. The third section 1123 extends from the first section 1121 toward the first side in the z direction. In the illustrated example, the third section 1123 is inclined relative to the z direction (the y-z plane). The shape of the third section 1123 is not specifically limited. In the illustrated example, the third section 1123 is rectangular as viewed in the x direction.

### Second Lead 12

The second lead 12 is spaced apart from the first lead 11 and is located on a second side in the x direction with respect to the die pad portion 111. The second lead 12 includes a second pad portion 121 and a plurality of second terminal portions 122.

The second pad portion 121 has a second-lead obverse surface 1211 and a second-lead reverse surface 1212. The second-lead obverse surface 1211 faces the first side in the z direction. The second-lead reverse surface 1212 faces the second side in the z direction. In the present embodiment, the second-lead obverse surface 1211 is at the same (or substantially the same) position as the first-lead obverse surface 1111 in the z direction. The second-lead obverse surface 1211 is where the connecting member 31 is electrically joined. The shape of the second pad portion 121 is not specifically limited. In the illustrated example, the second pad portion 121 has a rectangular shape that is longer in the y direction. As viewed in the z direction, the second pad portion 121 is smaller than the die pad portion 111. In the z direction, in addition, the second pad portion 121 is smaller than the die pad portion 111 and as large as the first terminal portion 112.

The second terminal portions 122 are arranged side by side in the y direction. Each second terminal portion 122 includes a fourth section 1221, a fifth section 1222, and a sixth section 1223.

The fourth section 1221 is connected to the second pad portion 121 and extends from the second pad portion 121 toward the second side in the x direction. In the illustrated example, the fourth section 1221 extends parallel (or substantially parallel) to the x-y plane. The surface of the fourth section 1221 facing the first side in the z direction is flush with the second-lead obverse surface 1211. The shape of the fourth section 1221 is not specifically limited. In the illustrated example, the fourth section 1221 is rectangular as viewed in the x direction.

The fifth section 1222 is located on the first side in the z direction with respect to the fourth section 1221. The fifth section 1222 is used for surface mounting of the semiconductor device A10 onto a circuit board or the like. The fifth section 1222 extends in the x direction.

The sixth section 1223 is located between the fourth section 1221 and the fifth section 1222. The sixth section 1223 extends from the fourth section 1221 toward the first side in the z direction. In the illustrated example, the sixth section 1223 is inclined relative to the z direction (the y-z plane). The shape of the sixth section 1223 is not specifically limited. In the illustrated example, the sixth section 1223 is rectangular as viewed in the x direction.

### Third Lead 13

The third lead 13 is spaced apart from the first lead 11 and the second lead 12 and is located on the second side in the x direction with respect to the die pad portion 111. The third lead 13 is aligned with the second lead 12 in the y direction. The third lead 13 includes a third pad portion 131 and a third terminal portion 132.

The third pad portion 131 has a third-lead obverse surface 1311 and a third-lead reverse surface 1312. The third-lead obverse surface 1311 faces the first side in the z direction. The third-lead reverse surface 1312 faces the second side in the z direction. In the present embodiment, the third-lead obverse surface 1311 is at the same (or substantially the same) position as the first-lead obverse surface 1111 in the z direction. The third-lead obverse surface 1311 is where the connecting member 32 is electrically joined. The shape of the third pad portion 131 is not specifically limited. In the illustrated example, the third pad portion 131 is rectangular as viewed in the z direction. The third pad portion 131 is smaller than the second pad portion 121 as viewed in the z direction. In the z direction, in addition, the third pad portion 131 is smaller than the die pad portion 111 and as large as the second pad portion 121.

The third terminal portion 132 includes a seventh section 1321, an eighth section 1322, and a ninth section 1323.

The seventh section 1321 is connected to the third pad portion 131 and extends from the third pad portion 131 toward the second side in the x direction. In the illustrated example, the seventh section 1321 extends parallel (or substantially parallel) to the x-y plane. The surface of the seventh section 1321 facing the first side in the z direction is flush with the third-lead obverse surface 1311. The shape of the seventh section 1321 is not specifically limited. In the illustrated example, the seventh section 1321 is rectangular as viewed in the x direction.

The eighth section 1322 is located on the first side in the z direction with respect to the seventh section 1321. The eighth section 1322 is used for surface mounting of the semiconductor device A10 onto a circuit board or the like. The eighth section 1322 extends in the x direction.

The ninth section 1323 is located between the seventh section 1321 and the eighth section 1322. The ninth section 1323 extends from the seventh section 1321 toward the first side in the z direction. In the illustrated example, the ninth section 1323 is inclined relative to the z direction (the y-z plane). The shape of the ninth section 1323 is not specifically limited. In the illustrated example, the ninth section 1323 is rectangular as viewed in the x direction.

### Fourth Lead 14

The fourth lead 14 is spaced apart from the first lead 11, the second lead 12, and the third lead 13 and is located on the second side in the x direction from the die pad portion 111. The fourth lead 14 is aligned with the second lead 12 and the third lead 13 in the y direction. The fourth lead 14 includes a fourth pad portion 141 and a fourth terminal portion 142.

The fourth pad portion 141 has a fourth-lead obverse surface 1411 and a fourth-lead reverse surface 1412. The fourth-lead obverse surface 1411 faces the first side in the z direction. The fourth-lead reverse surface 1412 faces the second side in the z direction. In the present embodiment, the fourth-lead obverse surface 1411 is at the same (or substantially the same) position as the first-lead obverse surface 1111 in the z direction. The fourth-lead obverse surface 1411 is where the connecting member 33 is electrically joined. The shape of the fourth pad portion 141 is not specifically limited. In the illustrated example, the fourth pad portion 141 is rectangular as viewed in the z direction. As viewed in the z direction, in addition, the fourth pad portion 141 is smaller than the second pad portion 121 and as large as the third pad portion 131. In the z direction, the fourth pad portion 141 is smaller than the die pad portion 111 and as large as the second pad portion 121 and the third pad portion 131.

The fourth terminal portion 142 includes a tenth section 1421, an eleventh section 1422, and a twelfth section 1423.

The tenth section 1421 is connected to the fourth pad portion 141 and extends from the fourth pad portion 141 toward the second side in the x direction. In the illustrated example, the tenth section 1421 extends parallel (or substantially parallel) to the x-y plane. The surface of the tenth section 1421 facing the first side in the z direction is flush with the fourth-lead obverse surface 1411. The shape of the tenth section 1421 is not specifically limited. In the illustrated example, the tenth section 1421 is rectangular as viewed in the x direction.

The eleventh section 1422 is located on the first side in the z direction with respect to the tenth section 1421. The eleventh section 1422 is used for surface mounting the semiconductor device A10 onto a circuit board or the like. The eleventh section 1422 extends in the x direction.

The twelfth section 1423 is located between the tenth section 1421 and the eleventh section 1422. The twelfth section 1423 extends from the tenth section 1421 toward the first side in the z direction. In the illustrated example, the twelfth section 1423 is inclined relative to the z direction (the y-z plane). The shape of the twelfth section 1423 is not specifically limited. In the illustrated example, the twelfth section 1423 is rectangular as viewed in the x direction.

### Semiconductor Element 20

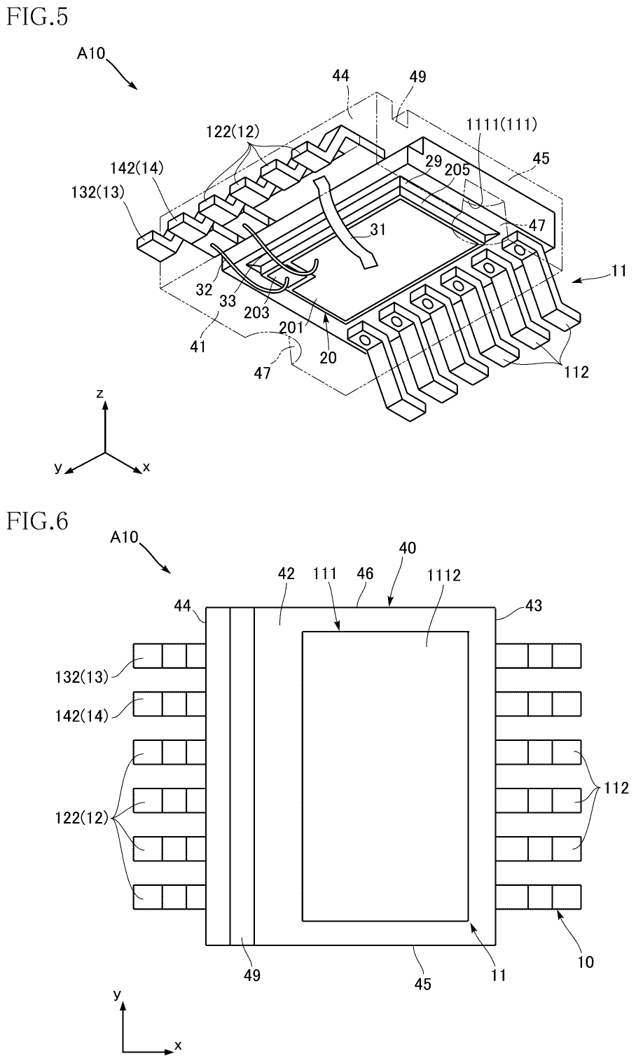

As shown in FIGS. 5 and 11 to 15, the semiconductor element 20 is mounted on the first-lead obverse surface 1111 of the die pad portion 111. For the semiconductor device A10, the semiconductor element 20 is a switching element. In one example, the switching element is an n-channel, vertical-type MOSFET (metal-oxide-semiconductor field-effect transistor). The semiconductor element 20, however, is not limited to a MOSFET. The semiconductor element 20 may be a different type of transistor, such as an IGBT (insulated gate bipolar transistor). In another example, the semiconductor element 20 may be a diode. The semiconductor element 20 includes a semiconductor layer 205, a first electrode 201, a second electrode 202, and a third electrode 203.

The semiconductor layer 205 includes a compound semiconductor substrate. The compound semiconductor substrate contains silicon carbide (SiC) as a main material. In an alternative example, the main material of the compound semiconductor substrate may be silico (Si).

The first electrode 201 is disposed on the side facing the same side as the first-lead obverse surface 1111 of the die pad portion 111 of the first lead 11 (disposed on the first side in the z direction). The first electrode 201 serves as the source electrode of the semiconductor element 20.

The second electrode 202 is disposed on the side opposite to the first electrode 201 in the z direction. The second electrode 202 faces the first-lead obverse surface 1111 of the die pad portion 111 of the first lead 11. The second electrode 202 serves as the drain electrode of the semiconductor element 20. In the present embodiment, the second electrode 202 is electrically joined to the first-lead obverse surface 1111 via a bonding layer 29. The bonding layer 29 is made from solder, silver (Ag) paste, or sintered silver, for example.

The third electrode 203 is disposed on the same side as the first electrode 201 in the z direction and spaced apart from the first electrode 201. The third electrode 203 serves as the gate electrode of the semiconductor element 20. As viewed in the z direction, the third electrode 203 is smaller in area than the first electrode 201.

### Connecting Members 31, 32, and 33

The connecting member 31 is joined to the first electrode 201 of the semiconductor element 20 and the second-lead obverse surface 1211 of the second pad portion 121 of the second lead 12. The material of the connecting member 31 is not specifically limited, and examples of the material include metals, such as aluminum (Al), copper (Cu), and gold (Au). In addition, the number of the connecting members 31 is not specifically limited, and a plurality of connecting members 31 may be provided. In the illustrated example, the connecting member 31 is a flat strip containing aluminum (Al).

The connecting member 32 is connected to the third electrode 203 of the semiconductor element 20 and the third-lead obverse surface 1311 of the third pad portion 131 of the third lead 13. In the illustrated example, the connecting member 32 is a thread containing gold (Au) and thinner than the connecting member 31.

The connecting member 33 is connected to the first electrode 201 of the semiconductor element 20 and the fourth-lead obverse surface 1411 of the fourth pad portion 141 of the fourth lead 14. In the illustrated example, the connecting member 33 is a thread containing gold (Au) and thinner than the connecting member 31.

In the present embodiment, the first terminal portions 112 of the first lead 11 are drain terminals, the second terminal portions 122 of the second lead 12 are source terminals, the third terminal portion 132 of the third lead 13 is a gate terminal, and the fourth terminal portion 142 of the fourth lead 14 is a source-sense terminal.

### Sealing Resin 40

As shown in FIGS. 1 to 15, the sealing resin 40 covers the semiconductor element 20, the connecting members 31, 32, and 33, and a portion of each of the first lead 11, the second lead 12, the third lead 13, and the fourth lead 14. The sealing resin 40 is electrically insulating. The sealing resin 40 may be made of a material containing a black epoxy resin, for example. The sealing resin 40 has a first resin surface 41, a second resin surface 42, a third resin surface 43, a fourth resin surface 44, a fifth resin surface 45, and a sixth resin surface 46.

The first resin surface 41 faces the same side as the first-lead obverse surface 1111 of the die pad portion 111 of the first lead 11 in the z direction (faces the first side in the z direction). The second resin surface 42 faces away from the first resin surface 41 in the z direction (faces the second side in the z direction). The first-lead reverse surface 1112 of the die pad portion 111 of the first lead 11 is exposed from the second resin surface 42. The second resin surface 42 and the first-lead reverse surface 1112 are flush with each other. The first-lead reverse surface 1112 is spaced apart from the third resin surface 43 in the x direction.

The third resin surface 43 faces the first side in the x direction. The first section 1121 of each first terminal portion 112 of the first lead 11 penetrates the third resin surface 43. The first section 1121 is spaced apart from the second resin surface 42 in the z direction.

The fourth resin surface 44 faces away from the third resin surface 43 in the x direction (faces the second side in the x direction). In the present embodiment, the fourth section 1221 of each second terminal portion 122 of the second lead 12, the seventh section 1321 of the third terminal portion 132 of the third lead 13, and the tenth section 1421 of the fourth terminal portion 142 of the fourth lead 14 penetrate the fourth resin surface 44. The fourth sections 1221, the seventh section 1321, and the tenth section 1421 are spaced apart from the second resin surface 42 in the z direction.

The fifth resin surface 45 and the sixth resin surface 46 face away from each other in the y direction.

In the illustrated example, the sealing resin 40 has a groove 49. The groove 49 is recessed from the second resin surface 42 in the z direction and extends in the y direction. The groove 49 extends to reach the fifth resin surface 45 and the sixth resin surface 46.

In the illustrated example, the sealing resin 40 has two recesses 47. One of the recesses 47 is recessed from the first resin surface 41 and the fifth resin surface 45. The other recess 47 is recessed from the first resin surface 41 and the sixth resin surface 46. Portions of the first-lead obverse surface 1111 are exposed from the recesses 47.

FIG. 16 shows the semiconductor device A10 in a state of use. In this example, the semiconductor device A10 is attached to a circuit board 92 by surface mounting. Specifically, the semiconductor device A10 is mounted by electrically joining, with solder 921 for example, the second sections 1122 of the first terminal portions 112, the fifth sections 1222 of the second terminal portions 122, the eighth section 1322 of the third terminal portion 132, and the eleventh section 1422 of the fourth terminal portion 142 to the wiring pattern (not shown) of the circuit board 92. Additionally, a heat sink 91 is placed to face the first-lead reverse surface 1112 of the die pad portion 111. In the illustrated example, a sheet material 919 is disposed between the first-lead reverse surface 1112 and the heat sink 91. The sheet material 919 may be an insulating sheet, for example.

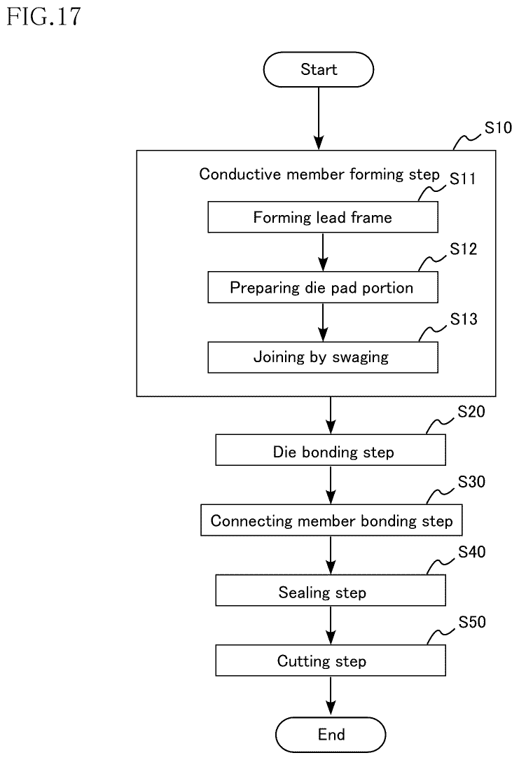

The following describes an example of a method for manufacturing a semiconductor device A10, with reference to FIGS. 17 to 22.

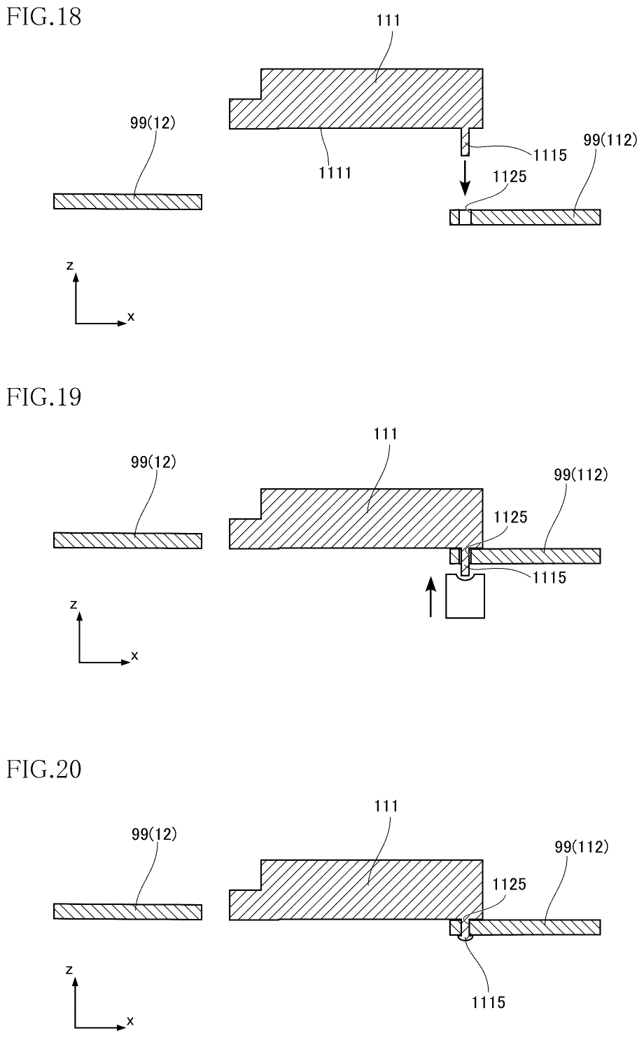

FIG. 17 is a flowchart of a method for manufacturing a semiconductor device A10. FIGS. 18 to 22 show the steps of an example of a method for manufacturing a semiconductor device A10. FIGS. 18 to 22 are sectional views corresponding to FIG. 12.

As shown in FIG. 17, the method for manufacturing a semiconductor device A10 includes a conductive member forming step S10, a die bonding step S20, a connecting member bonding step S30, a sealing step S40, and a cutting step S50.

In the conductive member forming step S10, a conductive member 10 is formed. This step begins with forming a lead frame 99 (S11). The lead frame 99 is formed from a metal plate by appropriate processing, including stamping and etching. The lead frame 99 as formed has portions that will be processed into a second lead 12, a third lead 13, a fourth lead 14, and a plurality of first terminal portions 112. The lead frame 99 also has a plurality of engaging holes 1125 extending in the z direction through the portions that will be processed into the first terminal portions 112 (see FIG. 18).

Next, a die pad portion 111 is prepared (S12). The die pad portion 111 is formed with a plurality of engaging portions 1115 protruding from the first-lead obverse surface 1111 in the z direction (see FIG. 18).

Next, the die pad portion 111 is joined to the lead frame 99 by swaging (S13). Specifically, as shown in FIGS. 18 and 19, the engaging portions 1115 of the die pad portion 111 are inserted into the engaging holes 1125 of the lead frame 99. Then, as shown in FIG. 19, while heat is applied, a die is pressed against the engaging portion 1115 from its tip. As a result, as shown in FIG. 20, the tip of the engaging portion 1115 deforms and engages with the engaging hole 1125, and the circumferential surface of the engaging portion 1115 makes intimate contact with the inner surface of the engaging hole 1125.

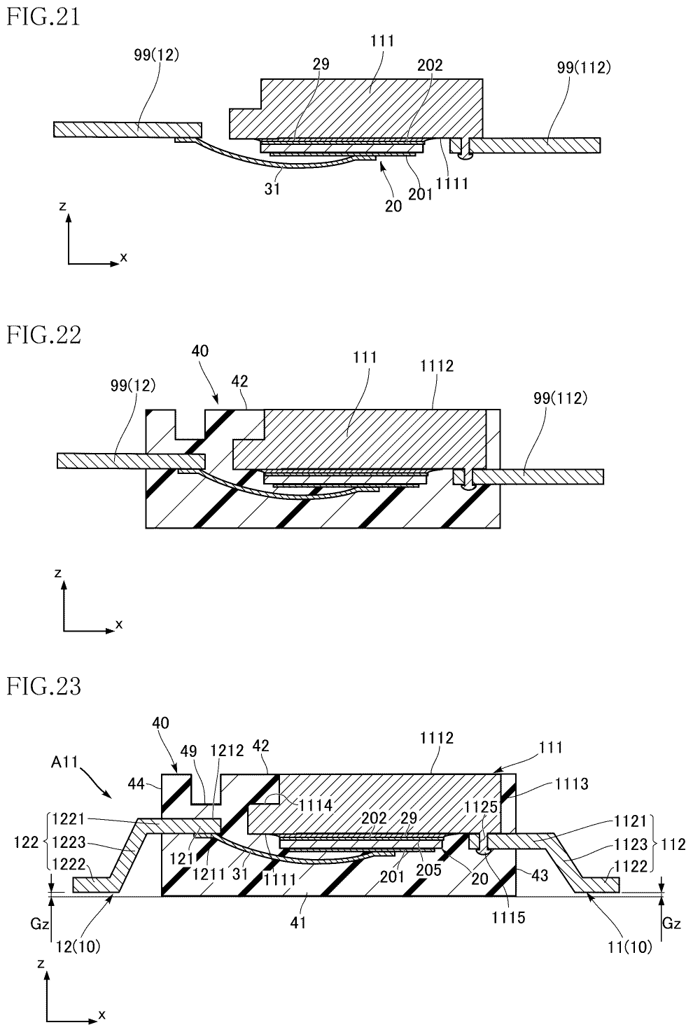

In the die bonding step S20, a semiconductor element 20 is attached to the die pad portion 111. This step begins with applying solder paste to the first-lead obverse surface 1111 of the die pad portion 111. Then, the semiconductor element 20 is placed on the applied solder paste. Then, a reflow process is preformed, causing the solder paste to melt and then solidify. Through the above processing, the semiconductor element 20 is joined to the die pad portion 111 via the bonding layer 29 (see FIG. 21). Note that the method of joining the semiconductor element 20 used in the die bonding step S20 is not specifically limited.

In the connecting member bonding step S30, connecting members 31, 32, and 33 are formed as shown in FIG. 21. In this step, the connecting member 31 is joined to the first electrode 201 of the semiconductor element 20 and a portion of the lead frame 99 that will be processed into the second lead 12. Likewise, the connecting member 32 is joined to the third electrode 203 and the portion of the lead frame 99 that will be processed into the third lead 13, and the connecting member 33 is joined to the first electrode 201 and the portion of the lead frame 99 that will be processed into the fourth lead 14. Note that the method of forming the connecting members 31, 32, and 33 used in the connecting member bonding step S30 is not specifically limited.

In the sealing step S40, a sealing resin 40 is formed. In this step, a resin material is hardened to form the sealing resin 40 that partly covers the lead frame 99 and the die pad portion 111 and fully covers the semiconductor element 20 and the connecting members 31, 32, and 33 as shown in FIG. 22. This step may be performed by a commonly known transfer molding process using a mold, for example. Specifically, the lead frame 99 with the die pad portion 111, the semiconductor element 20, and the connecting members 31, 32, and 33 joined thereto is placed in a molding machine. Then, a liquid resin is injected into the mold cavity and molded. The resin material is then hardened. In this way, the sealing resin 40 is formed. The lead frame 99 is placed with the first-lead reverse surface 1112 in contact with the mold, so that the first-lead reverse surface 1112 is exposed from the sealing resin 40. In addition, the first-lead reverse surface 1112 and the second resin surface 42 of the sealing resin 40 are flush with each other. Note that the method of forming the sealing resin 40 used in the sealing step S40 is not specifically limited.

In the cutting step S50, the lead frame 99 is cut. In this step, the lead frame 99 is cut into pieces with a blade, for example. In this way, a piece that will form the semiconductor device A10 is obtained. By cutting the lead frame 99, the second lead 12, the third lead 13, the fourth lead 14, and the plurality of first terminal portions 112 are formed. The first terminal portions 112 and the die pad portion 111 together form the first lead 11. Note that the method of cutting used in the cutting step S50 is not specifically limited. Then, bending is applied to the portions of the first terminal portions 112, the second terminal portions 122, the third terminal portion 132, and the fourth terminal portion 142 protruding from the sealing resin 40. Through the steps described above, the semiconductor device A10 described above is manufactured.

Note that the method for manufacturing a semiconductor device A10 is not limited to the one described above. For example, the die pad portion 111 may be joined in advance, and then the die pad portion 111 with the semiconductor element 20 is joined to the lead frame 99.

The following now describes the operation of the semiconductor device A10.

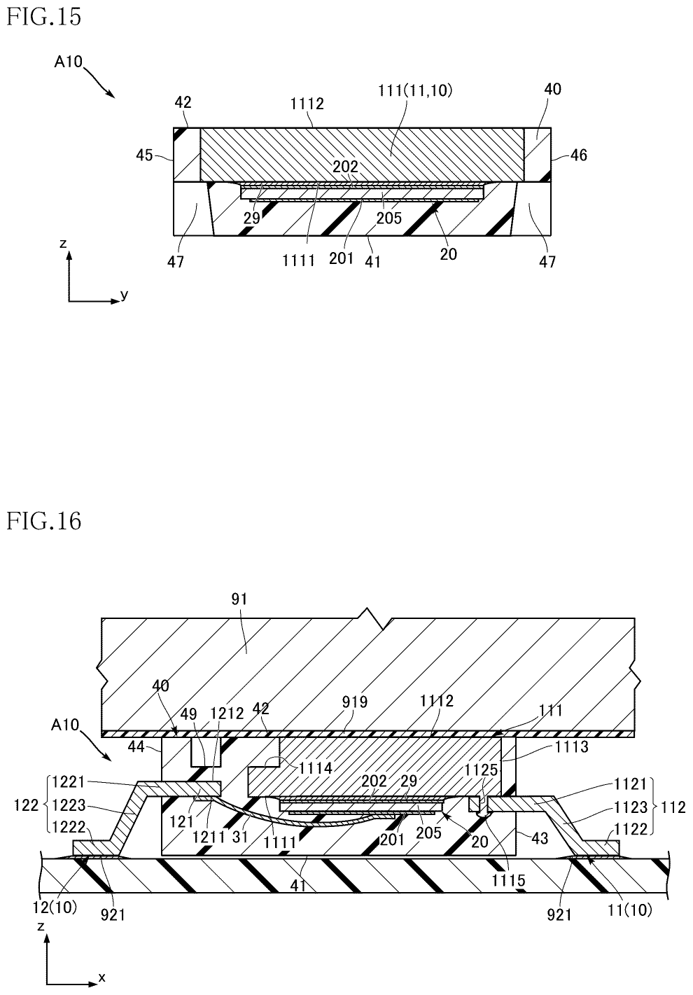

As shown in FIG. 15, the first-lead reverse surface 1112 is exposed from the second resin surface 42. Hence, the heat sink 91 or the like can be attached to face the first-lead reverse surface 1112. Additionally, the second section 1122 is located on the first side in the z direction from the first section 1121. The second sections 1122 can be used for surface mounting of the semiconductor device A10 on the circuit board 92 or the like. The first-lead reverse surface 1112 is spaced apart from the third resin surface 43 in the x direction. The first section 1121 is spaced apart from the second resin surface 42 in the z direction. That is, the sealing resin 40 is partly located between the first-lead reverse surface 1112 and the first section 1121. This enables the sealing resin 40 to firmly hold the first lead 11.

The die pad portion 111 is larger than the first section 1121 in length in the z direction. Consequently, heat transferred from the semiconductor element 20 can spread to a wider region in the x and y directions before reaching the first-lead reverse surface 1112. Thus, heat from the semiconductor element 20 can be efficiently released to the heat sink 91 or the like through a wider region of the first-lead reverse surface 1112. This effect increases with the length of the die pad portion 111 in the z direction. In the present embodiment, the die pad portion 111 has the first length t1 in the z direction that is at least six times and at most ten times the second length t2 of the first section 1121 in the z direction. The semiconductor device A10 can sufficiently improve the heat dissipation efficiency.

The first lead 11 is formed by joining the die pad portion 111 and the first terminal portions 112, which were separate components. Thus, the first lead 11 can be formed with the die pad portion 111 and the first terminal portions 112 that are greatly different in length in the z direction. For a first lead 11 formed from a lead frame having step-sectioned-strips, in contrast, the first length t1 of the die pad portion 111 in the z direction is limited and at most about five times the second length t2 of the first section 1121 in the z direction.

The first lead 11 is formed by inserting the engaging portions 1115 of the die pad portion 111 into the engaging holes 1125 of the first sections 1121 of the first terminal portion 112, followed by swaging the engaging portions 1115. In this way, the first terminal portions 112 are firmly joined to the die pad portion 111 to form the first lead 11 that is a single-piece component. This eliminates the need to use an additional component or material, such as a bonding material, for bonding the die pad portion 111 and the first terminal portions 112.

The first lead 11 includes the plurality of first terminal portions 112. This allows the semiconductor device A10 to achieve a higher mounting strength.

The sealing resin 40 is formed with the groove 49. This serves to increase the distance along the surface of the sealing resin 40 (hereinafter, creepage distance) from the first-lead reverse surface 1112 to the second lead 12 (each fourth section 1221), the third lead 13 (the seventh section 1321), and the fourth lead 14 (the tenth section 1421).

FIGS. 23 to 44 show other embodiments of the present disclosure. In these figures, the elements identical or similar to those of the above-described embodiment are denoted by the same reference numerals. In addition, the configuration of each part of any embodiment or variation can be combined unless a technical contradiction arises.

### First Variation of First Embodiment

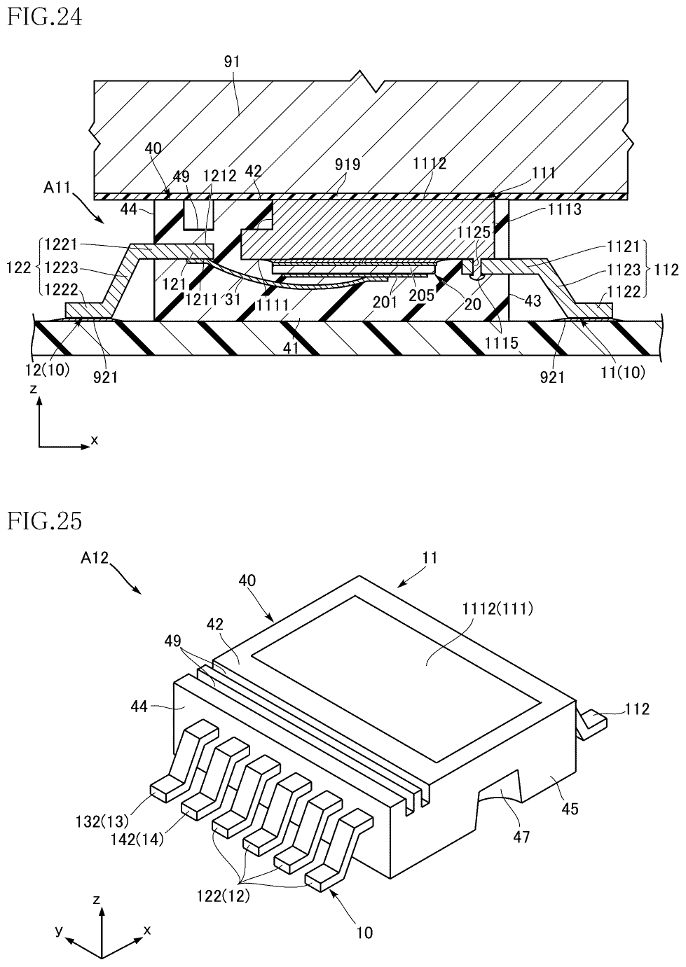

FIGS. 23 and 24 show a first variation of the semiconductor device A10. A semiconductor device A11 of the present variation differs from the above-described example in the arrangement of the second section 1122, the fifth section 1222, the eighth section 1322, and the eleventh section 1422 of the respective terminal portions relative to the first resin surface 41.

In the present variation, the second section 1122, the fifth section 1222, the eighth section 1322, and the eleventh section 1422 are located on the second side in the z direction (the side that the first-lead reverse surface 1112 faces) from the first resin surface 41. The surface of each of the second section 1122, the fifth section 1222, the eighth section 1322, and the eleventh section 1422 facing the first side in the z direction is a distance Gz away from the first resin surface 41.

The semiconductor device A11 according to the present variation is surface mountable and achieves the same effects as the semiconductor device A10 described above. In addition, the first resin surface 41 is located further from the second section 1122, the fifth section 1222, the eighth section 1322, and the eleventh section 1422 by the distance Gz toward the side in the first side in the z direction. Consequently, when the semiconductor device A11 is in the state of use shown in FIG. 24, a force pressing the heat sink 91 against the semiconductor device A11 usually results in pressing the first resin surface 41 that is pressed against the circuit board 92. This can reduce the force acting on the to the first lead 11, the second lead 12, the third lead 13, the fourth lead 14, and the semiconductor element 20 when a force is applied to the heat sink 91.

### Second Variation of First Embodiment

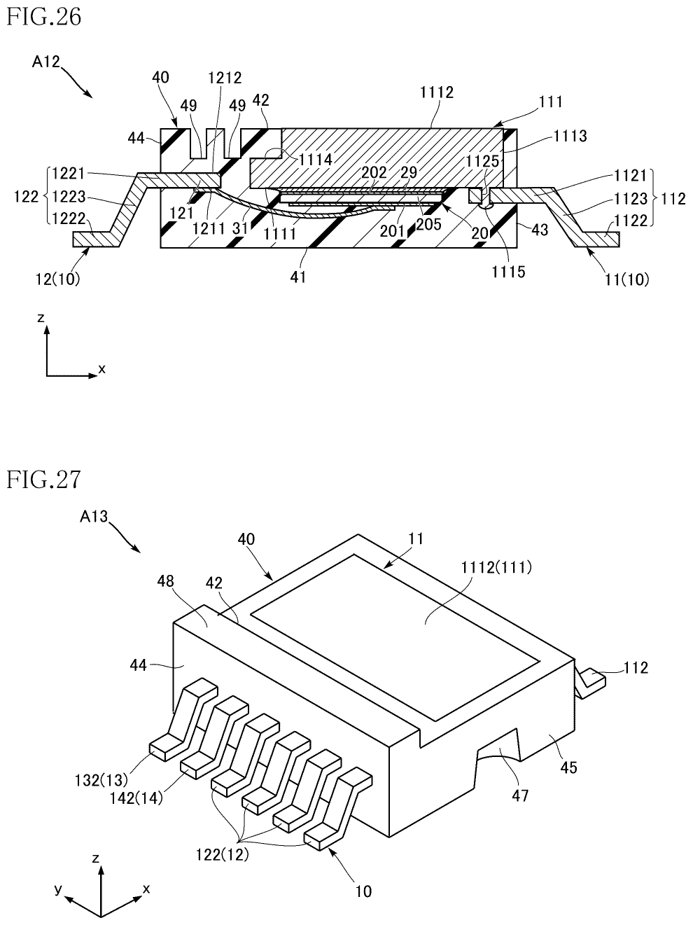

FIGS. 25 and 26 show a second variation of the semiconductor device A10. A semiconductor device A12 according to the present variation includes a sealing resin 40 that is provided with two grooves 49.

The grooves 49 extend in the y direction, reaching the fifth resin surface 45 and the sixth resin surface 46. The two grooves 49 are spaced apart from each other in the x direction.

The semiconductor device A12 according to the present variation is surface mountable and achieves the same effect as the examples described above. In addition, the presence of the two grooves 49 serves to further increase the creepage distance from the first-lead reverse surface 1112 to the second terminal portions 122, the third terminal portion 132, and the fourth terminal portion 142. As the present variation indicates, the number of grooves 49 to be provided is not specifically limited.

### Third Variation of First Embodiment

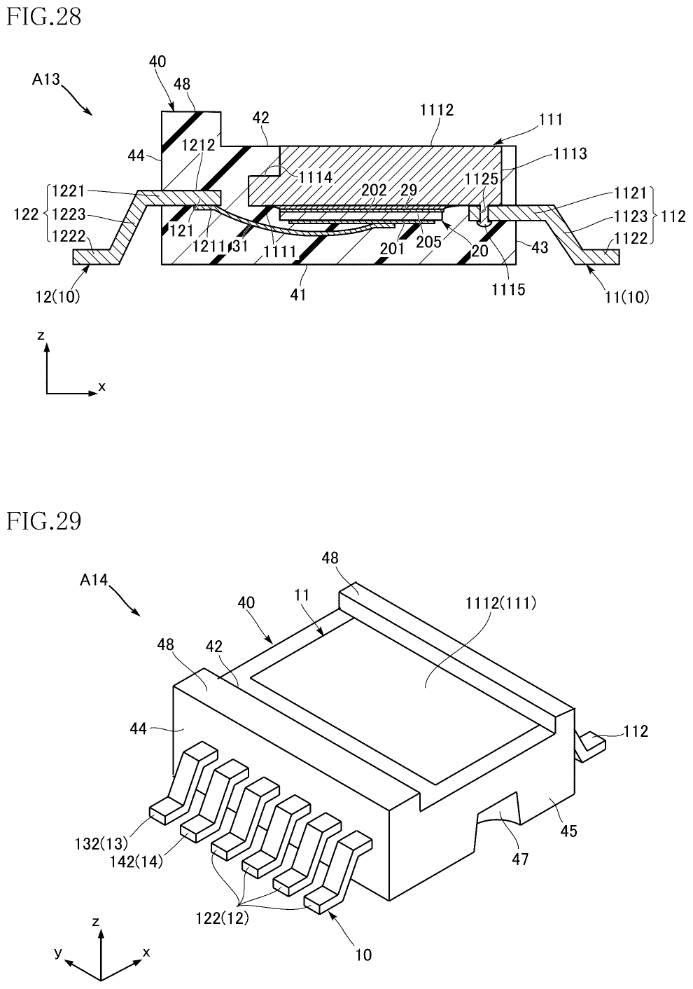

FIGS. 27 and 28 show a third variation of the semiconductor device A10. A semiconductor device A13 according to the present variation includes a sealing resin 40 that is provided with a protrusion 48.

The protrusion 48 protrudes from the second resin surface 42 toward the second side in the z direction. The protrusion 48 extends in the y direction, reaching the fifth resin surface 45 and the sixth resin surface 46. In the illustrated example, the protrusion 48 is located along the edge of the sealing resin 40 on the second side in the x direction and thus in contact with the fourth resin surface 44.

The semiconductor device A13 according to the present variation is surface mountable. In addition, the presence of the protrusion 48 serves to increase the creepage distance from the first-lead reverse surface 1112 to the second terminal portions 122, the third terminal portion 132, and the fourth terminal portion 142.

### Fourth Variation of First Embodiment

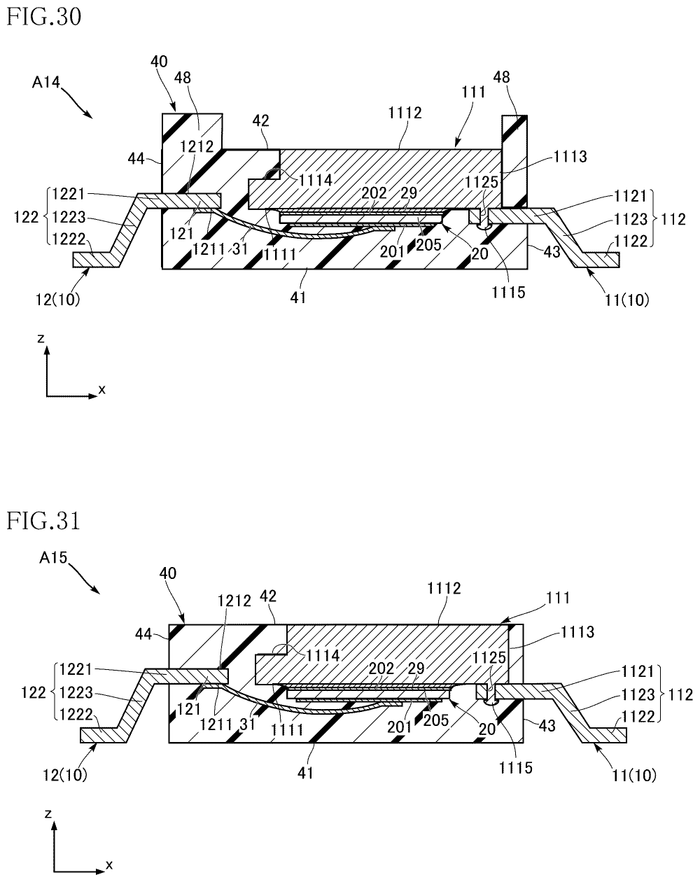

FIGS. 29 and 30 show a fourth variation of the semiconductor device A10. A semiconductor device A14 according to the present variation includes a sealing resin 40 that is provided with two protrusions 48.

Each protrusion 48 protrudes from the second resin surface 42 toward the second side in the z direction. Each protrusion 48 extends in the y direction, reaching the fifth resin surface 45 and the sixth resin surface 46. The two protrusions 48 are spaced apart from each other across the first-lead reverse surface 1112 in the x direction. One of the protrusions 48 is in contact with the fourth resin surface 44, and the other with the third resin surface 43.

The semiconductor device A14 according to the present variation is surface mountable. In addition, the presence of the two protrusions 48 serves to further increase the creepage distance from the first-lead reverse surface 1112 to the second terminal portions 122, the third terminal portion 132, and the fourth terminal portion 142. As the present variation indicates, the number of protrusions 48 to be provided is not specifically limited.

### Fifth Variation of First Embodiment

FIG. 31 shows a fifth variation of the semiconductor device A10. A semiconductor device A15 according to the present variation includes a sealing resin 40 without the protrusions 48 and the grooves 49 described above. The semiconductor device A15 according to the present variation is surface mountable. As the present variation indicates, the sealing resin 40 may be without the protrusion 48 and the groove 49.

### Sixth Variation of First Embodiment

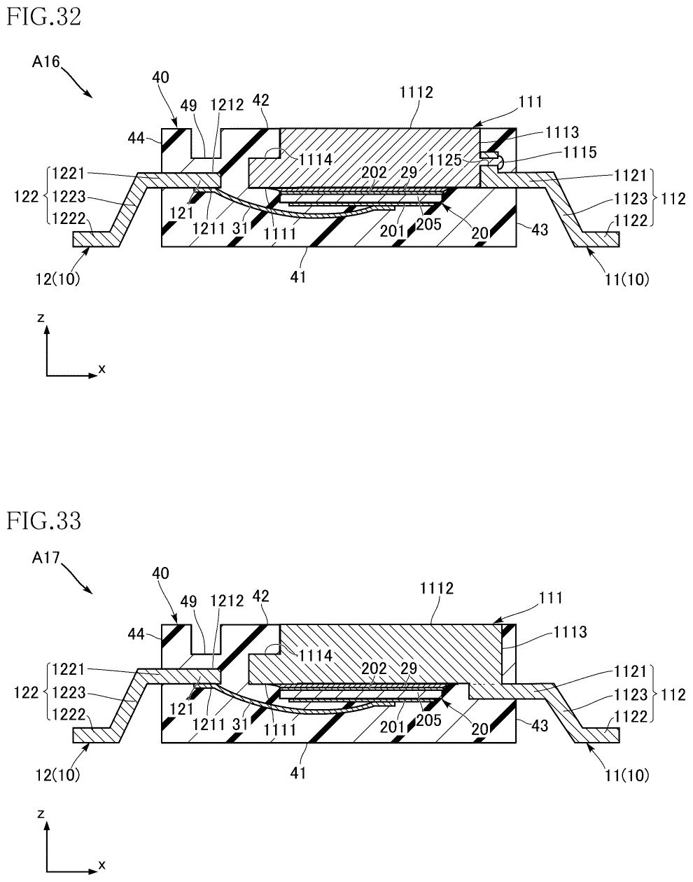

FIG. 32 shows a sixth variation of the semiconductor device A10. In a semiconductor device A16 of the present variation, the locations on the die pad portion 111 to which the first terminal portions 112 are joined are different from those in the above example.

The die pad portion 111 according to the present variation includes a plurality of engaging portions 1115 protruding from the first-lead side surface 1113 in the x direction and arranged at equal intervals in the y direction. Each first terminal portion 112 according to the present variation includes a first section 1121 that is L-shaped as viewed in the y direction and an engaging hole 1125 that extends through the first section 1121 in the x direction. According to the present variation, each first terminal portion 112 (the first section 1121) is joined to the first-lead side surface 1113 of the die pad portion 111 by inserting the engaging portion 1115 into the engaging hole 1125 and swaging the engaging portion 1115. According to the present variation, in addition, the surface of the first section 1121 of each first terminal portion 112 facing toward the first side in the z direction is flush with the first-lead obverse surface 1111. That is, the surface of the first section 1121 facing toward the first side in the z direction, the first-lead obverse surface 1111, the surface of the fourth section 1221 facing toward the first side in the z direction, and the second-lead obverse surface 1211 all have the same position (or substantially the same position) in the z direction.

The semiconductor device A16 according to the present variation is surface mountable. As the present variation indicates, there is no particular limitation on the locations on the die pad portion 111 to which the first terminal portions 112 are joined.

### Seventh Variation of First Embodiment

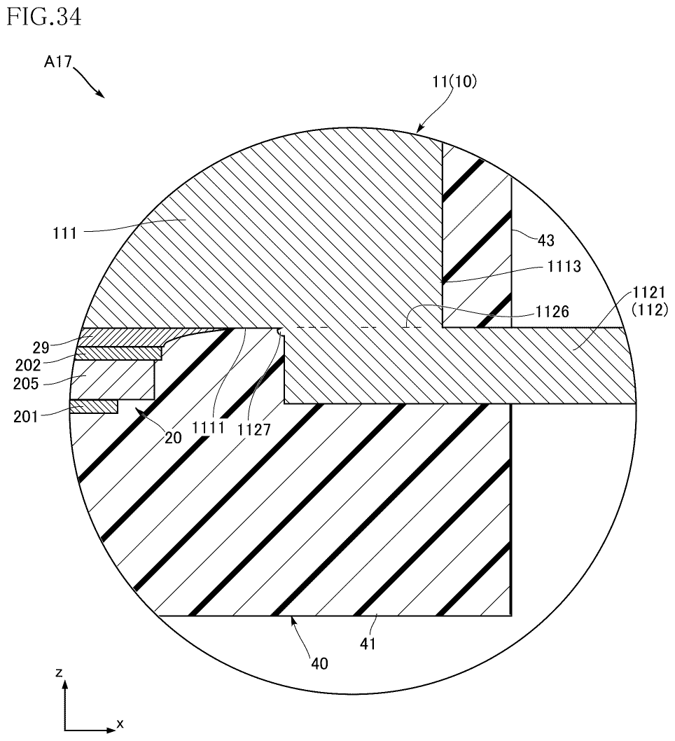

FIGS. 33 and 34 show a seventh variation of the semiconductor device A10. For a semiconductor device A17 of the present variation, a different joining method is used to join the die pad portion 111 and the first terminal portions 112.

According to the present variation, the first lead 11 includes the die pad portion 111 and the first terminal portions 112 each of which is joined by ultrasonic welding. Specifically, the die pad portion 111 and the first terminal portion 112 (the first section 1121) are pressed against each other in a direction orthogonal to the contact surfaces of the die pad portion 111 and the first terminal portion 112. In this state, ultrasonic vibration is applied in a direction parallel to the contact surfaces of the die pad portion 111 and the first terminal portion 112. This causes solid-state welding in which the contact surfaces of the die pad portion 111 and the first terminal portion 112 are activate and joined together. Note that the “orthogonal direction” is not limited to the one that is strictly 90° to the contact surfaces and includes a direction that is approximately 90° to the contact surface. In addition, the “parallel direction” is not limited to the one that is exactly parallel to the contact surfaces and includes a direction that is roughly parallel to the contact surface. By the ultrasonic welding, the die pad portion 111 and the first terminal portions 112 (the first sections 1121) are joined together as a single piece. Note that it is not necessary that the first section 1121 is bonded to the first-lead obverse surface 1111 across the entire boundary surface 1126 in contact with the first-lead obverse surface 1111. As shown in FIG. 34, the boundary surface 1126 may include a portion not bonded to the first-lead obverse surface 1111. Bonding at least about 30% of the boundary surface 1126 can provide sufficient mechanical strength and sufficient electrical conductivity. As shown in FIG. 34, in addition, the first section 1121 has a ridge 1127 formed at the boundary with the die pad portion 111 (the first-lead obverse surface 1111) as a result of splash occurring in the ultrasonic welding process. The ridge 1127 is raised in a direction crossing the direction in which the boundary surface 1126 faces (the direction crossing the z direction). In the ultrasonic welding process, pressure and ultrasonic vibration are applied until the ridge 1127 is formed, so that the first-lead obverse surface 1111 and the boundary surface 1126 are joined together to achieve sufficient strength and electrical conductivity.

The semiconductor device A17 according to the present variation is surface mountable. The first lead 11 of this variation is formed by joining the first sections 1121 of the first terminal portions 112 and the die pad portion 111 by ultrasonic welding. Thus, the first terminal portions 112 are firmly joined to the die pad portion 111 to form the first lead 11 that is a single-piece component. That is, the die pad portion 111 and the first terminal portions 112 are joined together without the need to form the die pad portion 111 with engaging portions 1115 or the first terminal portions 112 with the engaging holes 1125 or to use a bonding material or other joining material.

### Eighth Variation of First Embodiment

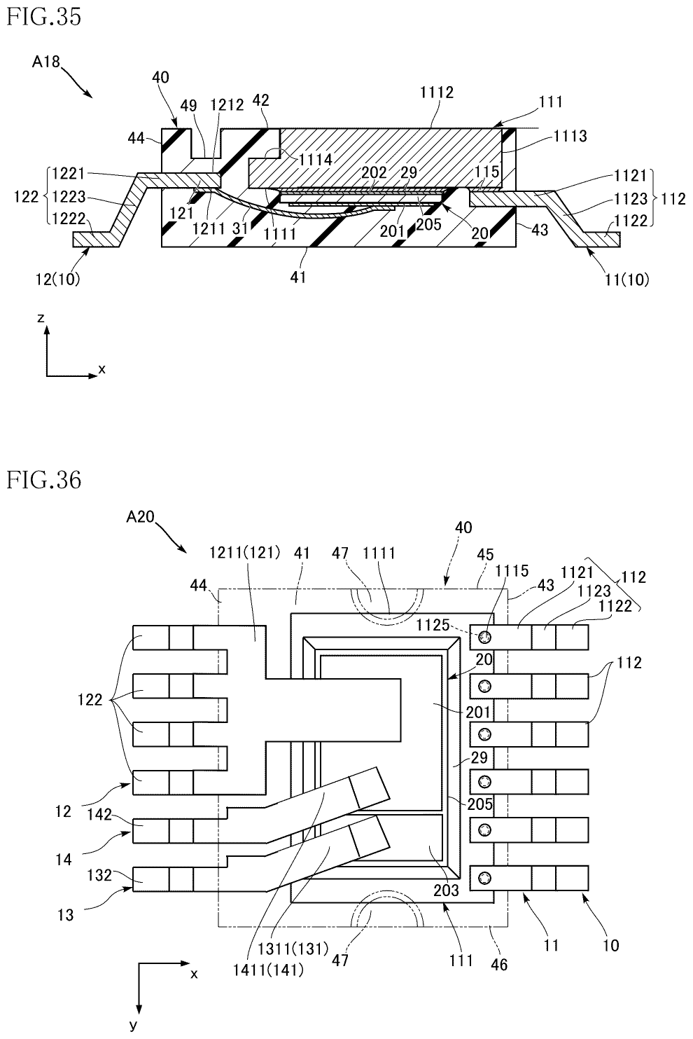

FIG. 35 shows an eighth variation of the semiconductor device A10. For a semiconductor device A18 of the present variation, a different joining method is used to join the die pad portion 111 and the first terminal portions 112.

According to the present variation, the first lead 11 includes the die pad portion 111 and the first terminal portions 112 that are joined via a bonding layer 115. That is, the bonding layer 115 is interposed between the die pad portion 111 and each first section 1121. The bonding layer 115 is a layer of solder, silver (Ag) paste, or sintered silver, for example.

The semiconductor device A18 according to the present variation is surface mountable. In addition, the die pad portion 111 and the first terminal portions 112 are joined via the bonding layer 115 and thus without the need to form the die pad portion 111 with engaging portions 1115 or the first terminal portions 112 with the engaging holes 1125.

As can be seen from the seventh and eighth variations, the method of joining the die pad portion 111 and the first terminal portions 112 is not specifically limited. The die pad portion 111 and the first terminal portions 112 can be joined together by other methods (including mechanical joining using screws, rivets, or the like, and metallurgically joining, such as welding).

### Second Embodiment

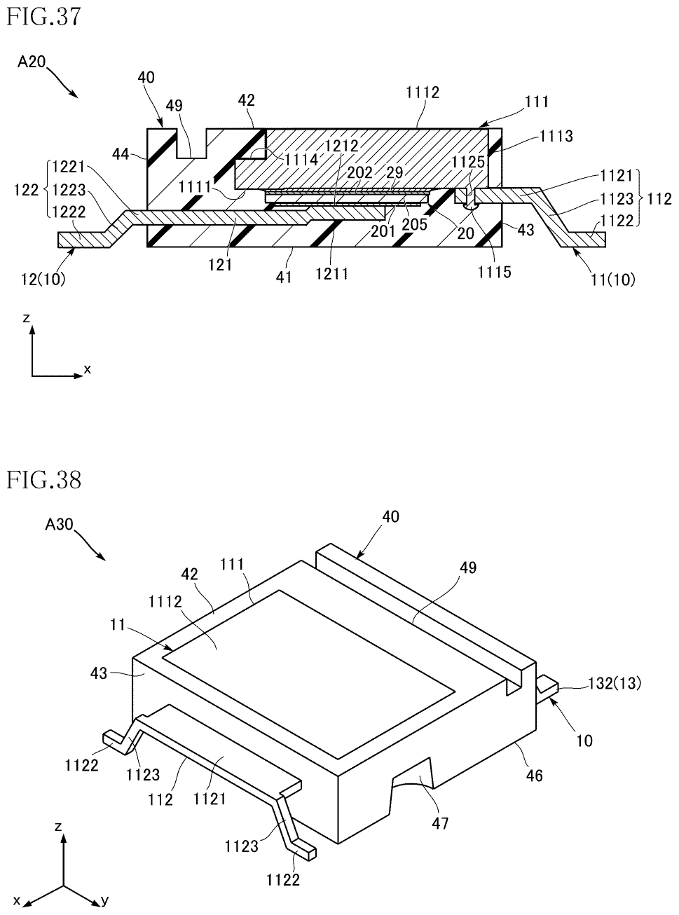

FIGS. 36 and 37 show a semiconductor device according to a second embodiment of the present disclosure. Unlike the first embodiment, the semiconductor device A20 of the present embodiment does not include the connecting members 31, 32, and 33. The configuration and operation of other parts of the present embodiment are the same as those of the first embodiment. Note that various parts of the first embodiment and the variations may be combined in any suitable manner.

In the present embodiment, the second lead 12 includes a second pad portion 121 with a second-lead reverse surface 1212 joined and electrically connected to the first electrode 201 of the semiconductor element 20. The third lead 13 includes a third pad portion 131 with a third-lead reverse surface 1312 joined and electrically connected to the third electrode 203 of the semiconductor element 20. The fourth lead 14 includes a fourth pad portion 141 with a fourth-lead reverse surface 1412 joined and electrically connected to the first electrode 201 of the semiconductor element 20.

The semiconductor device A20 according to the present embodiment is surface mountable. In the present embodiment, in addition, the second pad portion 121, the third pad portion 131, and the fourth pad portion 141 are electrically connected to the first electrode 201, the third electrode 203, and the first electrode 201, respectively. This allows the passage of a larger current than a configuration in which the second pad portion 121, the third pad portion 131, and the fourth pad portion 141 are electrically connected to the semiconductor element 20 via the connecting members 31, 32, and 33. In addition, the semiconductor device A20 does not require the connecting members 31, 32, and 33. As can be seen from the present embodiment, the configuration for electrically connecting the second, third and fourth leads 12, 13 and 14 and the semiconductor element 20 is not specifically limited.

### Third Embodiment

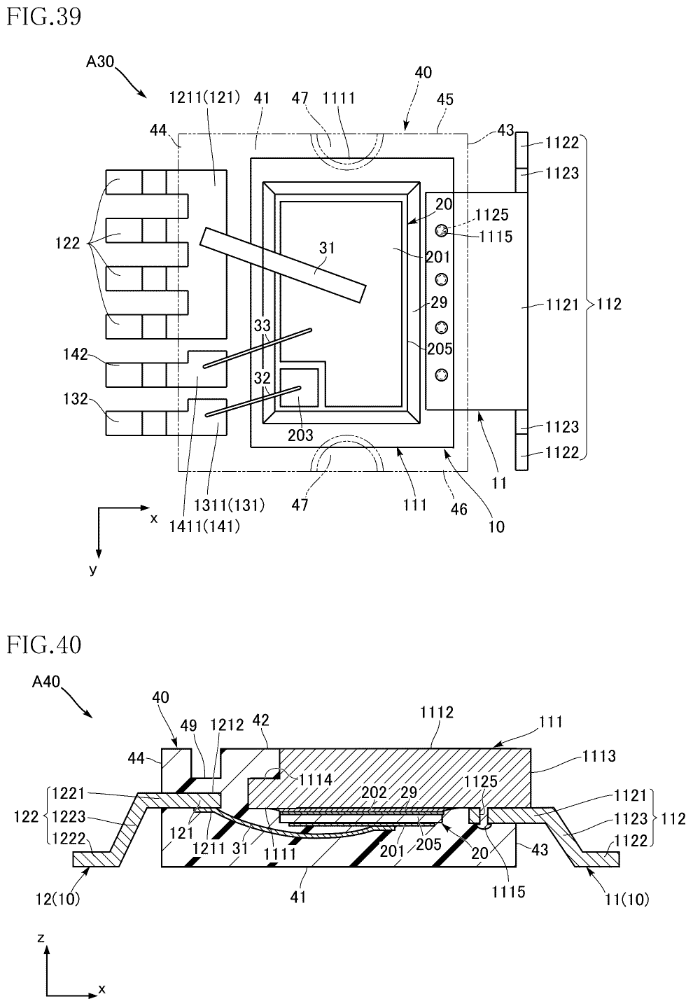

FIGS. 38 and 39 show a semiconductor device according to a third embodiment of the present disclosure. A semiconductor device A30 according to the present embodiment includes the first terminal portions 112 having a shape different from those of the embodiments described above. The configuration and operation of other parts of the present embodiment are the same as those of the first embodiment. Note that various parts of the first and second embodiments and the variations may be combined in any suitable manner.

The present embodiment includes a first lead 11 provided with a single first terminal portion 112. The first terminal portion 112 includes a first section 1121, two second sections 1122, and two third sections 1123.

The first section 1121 is joined to the first-lead obverse surface 1111 of the die pad portion 111. The first section 1121 includes a plurality of engaging holes 1125 extending in the z direction through the first section 1121. The engaging holes 1125 are equally spaced apart in the y direction. The first section 1121 is joined to the die pad portion 111 by inserting the engaging portions 1115 of the die pad portion 111 through the engaging holes 1125 and swaging the engaging portions 1115. The first section 1121 extends from the die pad portion 111 toward the first side in the x direction. In the illustrated example, the first section 1121 extends parallel (or substantially parallel) to the x-y plane. The first section 1121 penetrates the third resin surface 43. The shape of the first section 1121 is not specifically limited. In the illustrated example, the first section 1121 is rectangular as viewed in the z direction.

The two second sections 1122 are located on the first side in the z direction with respect to the first section 1121. The two second sections 1122 are used for surface mounting of the semiconductor device A30 onto a circuit board or the like.

Each of the two third sections 1123 is located between the first section 1121 and one of the two second sections 1122. Each third section 1123 extends from the first section 1121 toward the first side in the z direction. In the illustrated example, each third section 1123 extends outward from the first section 1121 in the y direction and is inclined relative to the z direction. The third sections 1123 are parallel (or substantially parallel) to the y-z plane. The shape of the third sections 1123 is not specifically limited. In the illustrated example, the third sections 1123 are rectangular as viewed in the z direction.

In the present embodiment, each of the two second sections 1122 extend outward from one of the two third sections 1123 in the y direction. Each second section 1122 is parallel (or substantially parallel) to the y direction. Neither of the two second sections 1122 extends beyond the third sections 1123 toward the first side in the x direction. In the illustrated example, the two second sections 1122 and the two third sections 1123 are at the same (or substantially the same) position in the x direction.

The semiconductor device A30 according to the present embodiment is surface mountable. In addition, with the third sections 1123 is parallel (or substantially parallel) to the y-z plane and the second sections 1122 do not extend past the third sections 1123 in the x direction, the semiconductor device A30 can be made compact in the x direction. With the two second sections 1122 extending outward in the x direction from the relevant third section 1123, the semiconductor device A30 can achieve a higher mounting strength. As can be seen from the present embodiment, the shape of the first terminal portion 112 is not specifically limited.

### Fourth Embodiment

FIG. 40 shows a semiconductor device according to a fourth embodiment of the present disclosure. A semiconductor device A40 according to the present embodiment includes a first lead 11 of a configuration different from that of the embodiments described above. The configuration and operation of other parts of the present embodiment are the same as those of the first embodiment. Note that various parts of the first through third embodiments and the variations may be combined in any suitable manner.

In the present embodiment, the first-lead side surface 1113 is located on the first side in the x direction from the third resin surface 43. That is, the first-lead reverse surface 1112 has a portion located on the first side in the x direction from the third resin surface 43 as viewed in the z direction.

The semiconductor device A40 according to the present embodiment is surface mountable. The first-lead reverse surface 1112 having a portion extending toward the first side in the x direction beyond the third resin surface 43 provides a larger area that can face the heat sink 91. This can increase the heat disputation efficiency of the semiconductor device A40 to the heat sink 91.

### Fifth Embodiment

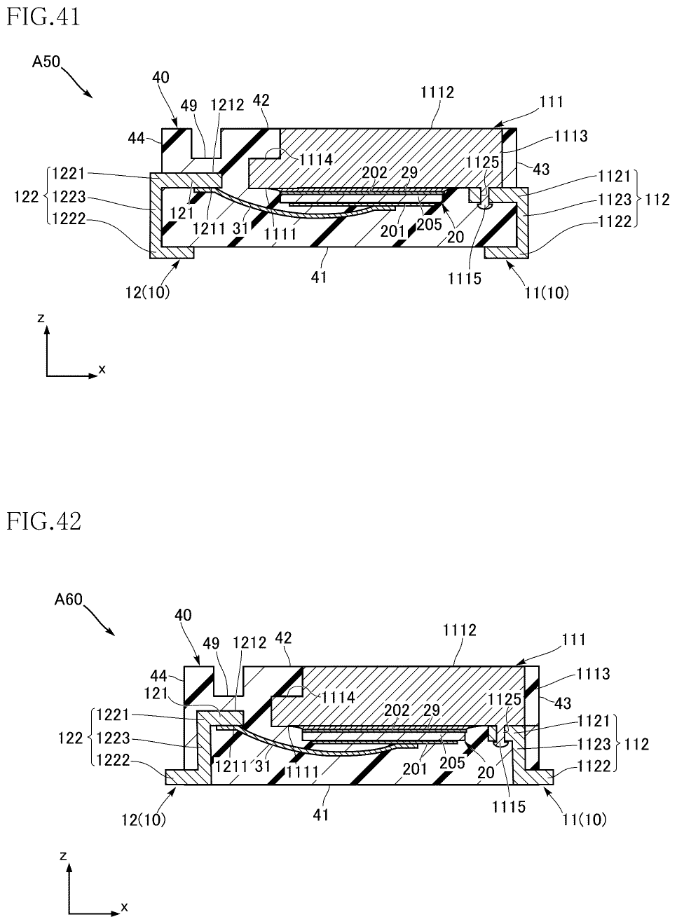

FIG. 41 shows a semiconductor device according to a fifth embodiment of the present disclosure. A semiconductor device A50 according to the present embodiment includes the first to fourth terminal portions 112, 122, 132 and 142 each having a shape different from those of the embodiments described above. The configuration and operation of other parts of the present embodiment are the same as those of the first embodiment. Note that various parts of the first through fourth embodiments and the variations may be combined in any suitable manner.

For each first terminal portion 112 of the present embodiment, the third section 1123 extends from the end of the first section 1121 on the first side in the x direction toward the first side in the z direction along the third resin surface 43. The second section 1122 extends from the end of the third section 1123 on the first side in the z direction toward the second side in the x direction along the first resin surface 41. For each second terminal portion 122 of the present embodiment, the sixth section 1223 extends from the end of the fourth section 1221 on the second side in the x direction toward the first side in the z direction along the fourth resin surface 44. The fifth section 1222 extends from the end of the sixth section 1223 on the first side in the z direction toward the first side in the x direction along the first resin surface 41. For the third terminal portion 132 of the present embodiment, although not shown in the figure, the ninth section 1323 extends from the end of the seventh section 1321 on the second side in the x direction toward the first side in the z direction along the fourth resin surface 44. The eighth section 1322 extends from the end of the ninth section 1323 on the first side in the z direction toward the first side in the x direction along the first resin surface 41. For the fourth terminal portion 142 of the present embodiment, the twelfth section 1423 extends from the end of the tenth section 1421 on the second side in the x direction toward the first side in the z direction along the fourth resin surface 44. The eleventh section 1422 extends from the end of the twelfth section 1423 on the first side in the z direction toward the first side in the x direction along the first resin surface 41.

The semiconductor device A50 according to the present embodiment is surface mountable. According to the present embodiment, in addition, the second sections 1122, the fifth sections 1222, the eighth section 1322, and the eleventh section 1422 all extend inward in the x direction. With such terminal portions, the mounting area (the length in the x direction) of the semiconductor device A50 can be smaller than that of a device with the terminal portions extending outward (called gullwing terminals). As can be seen from the present embodiment, the shapes of the first to fourth terminal portions 112, 122, 132, and 142 are not specifically limited.

### Sixth Embodiment

FIG. 42 shows a semiconductor device according to a sixth embodiment of the present disclosure. A semiconductor device A60 according to the present embodiment includes the first to fourth terminal portions 112, 122, 132 and 142 each having a configuration different from those of the embodiments described above. The configuration and operation of other parts of the present embodiment are the same as those of the first embodiment. Note that various parts of the first through fifth embodiments and the variations may be combined in any suitable manner.

Each first terminal portions 112 of the present embodiment is configured such that the first section 1121 does not penetrate through the third resin surface 43, that the third section 1123 extends in the z direction within the sealing resin 40, and that the second section 1122 is exposed from the first resin surface 41. Each second terminal portion 122 is configured such that the fourth section 1221 does not penetrate through the fourth resin surface 44, that the sixth section 1223 extends in the z direction within the sealing resin 40, and that the fifth section 1222 is exposed from the first resin surface 41. Although not illustrated in the figure, the third terminal portion 132 is configured such that the seventh section 1321 does not penetrate the fourth resin surface 44, that the ninth section 1323 extends in the z direction within the sealing resin 40, and that the eighth section 1322 is exposed from the first resin surface 41. Similarly, the fourth terminal portion 142 is configured such that the tenth section 1421 does not penetrate through the fourth resin surface 44, that the twelfth section 1423 extends in the z direction within the sealing resin 40, and that the eleventh section 1422 is exposed from the first resin surface 41.

The semiconductor device A60 according to the present embodiment is surface mountable. Additionally, the mounting area (the length in the x direction) of the semiconductor device A60 can be smaller as compared with a device with the first to fourth terminal portions 112, 122, 132, and 142 protruding outward in the x direction from the third resin surface 43 or the fourth resin surface 44. As can be seen from the present embodiment, the configurations of the first to fourth terminal portions 112, 122, 132, and 142 are not specifically limited.

### First Variation of Sixth Embodiment

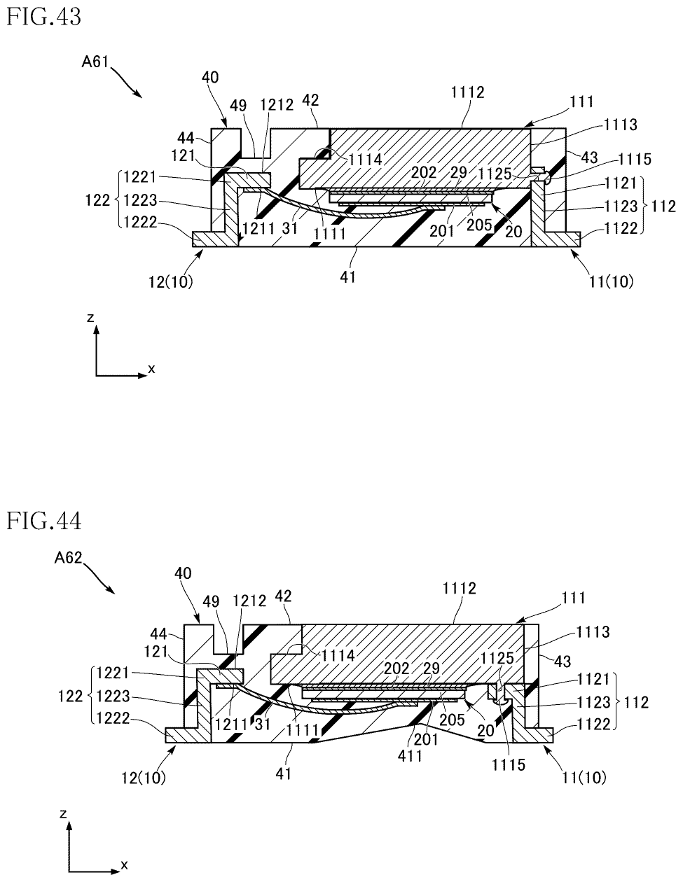

FIG. 43 shows a first variation of the semiconductor device A60. For a semiconductor device A61 of the present variation, the locations on the die pad portion 111 to which the first terminal portions 112 are joined are different from those in the sixth embodiment.

The die pad portion 111 of the present variation has a plurality of engaging portions 1115 extending in the x direction from the first-lead side surface 1113 and arranged at equally spaced intervals in the y direction. Each first terminal portion 112 of the present variation has a first section 1121 connected to the end of the third section 1123 on the second side in the z direction and extending toward the second side in the z direction. Each first section 1121 has an engaging hole 1125 extending therethrough in the x direction. In the present variation, the first terminal portions 112 (the first sections 1121) are joined to the first-lead side surface 1113 of the die pad portion 111 by inserting the engaging portions 1115 into the engaging holes 1125 and swaging the engaging portions 1115.

The semiconductor device A61 according to the present variation is surface mountable and achieves the same effect as the examples described above. As can be seen from the present variation, the locations on the die pad portion 111 where the first terminal portions 112 are joined are not specifically limited.

### Second Variation of Sixth Embodiment

FIG. 44 shows a second variation of the semiconductor device A60. A semiconductor device A62 according to the present variation includes a sealing resin 40 formed with a recessed region 411. The recessed region 411 is recessed in the z direction from the first resin surface 41. The recessed region 411 is located between the second sections 1122 and the fifth, eighth section, and eleventh sections 1222, 1322, and 1422 in the x direction. In the present variation, the recessed region 411 is gradually recessed toward the second side in the z direction with approach from a portion near the second sections 1122 toward the second side in the x direction. Also, the recessed region 411 is gradually recessed toward the second side in the z direction with approach from a portion near the fifth section 1222, the eighth section 1322, and the eleventh section 1422 toward the first side in the x direction. The recessed region 411 is formed so as not interfere with the semiconductor element 20 and the connecting members 31, 32, and 33.

The semiconductor device A62 according to the present variation is surface mountable and achieves the same effect as the examples described above. Additionally, the presence of the recessed region 411 in the sealing resin 40 serves to increase the distance along the surface of the sealing resin 40 (creepage distance) from the second section 1122 to the fifth section 1222, the eighth section 1322, and the eleventh section 1422. The recessed region 411 is not limited to the one having one gradual recess as in the present variation. The recessed region 411 may include a plurality of recesses.

The semiconductor device and the method for manufacturing a semiconductor device according to the present disclosure are not limited to the above-described embodiments. Various design changes may be made freely in the specific structure of each part of the semiconductor device and the specific processing in each step of the method for manufacturing a semiconductor device according to the present disclosure. The present disclosure includes embodiments described in the following clauses.

### Clause 1

A semiconductor device comprising:
a semiconductor element;
a first lead including a die pad portion and a first terminal portion, the die pad portion including a first-lead obverse surface facing a first side in a thickness direction and on which the semiconductor element is mounted, a first-lead reverse surface facing a second side in the thickness direction, and a first-lead side surface facing a first side in a first direction orthogonal to the thickness direction; and
a sealing resin including a first resin surface facing the first side in the thickness direction and a second resin surface facing the second side in the thickness direction, the sealing resin covering a portion of the die pad portion,
wherein the first-lead reverse surface is exposed from the second resin surface, and
the first terminal portion includes a first section joined to the die pad portion, a second section located on the first side in the thickness direction with respect to the first section and used for mounting, and a third section between the first section and the second section.

### Clause 2

The semiconductor device according to Clause 1, wherein the first section is joined to the first-lead obverse surface.

### Clause 3

The semiconductor device according to Clause 1, wherein the first section is joined to the first-lead side surface.

### Clause 4

The semiconductor device according to any one of Clauses 1 to 3, wherein the die pad portion further includes an engaging portion,
the first section includes an engaging hole for engagement with the engaging portion, and
the engaging portion is swaged into the engaging hole.

### Clause 5

The semiconductor device according to any one of Clauses 1 to 3, wherein the die pad portion and the first section are in contact with and integral with each other, and
the first section includes a ridge formed at a boundary with the die pad portion, the ridge being raised in a direction crossing a direction in which a boundary surface between the first section and the die pad portion faces.

### Clause 6

The semiconductor device according to any one of Clauses 1 to 3, further comprising a bonding layer between the die pad portion and the first section.

### Clause 7

The semiconductor device according to any one of Clauses 1 to 6, further comprising a second lead spaced apart from the first lead,
wherein the second lead includes a second pad portion and a second terminal portion connected to the second pad portion,
the second terminal portion includes a fourth section connected to the second pad portion, a fifth section located on the first side in the thickness direction with respect to the fourth section and used for mounting, and a sixth section between the fourth section and the fifth section, and
the sealing resin further includes a third resin surface facing the first side in the first direction and a fourth resin surface facing a second side in the first direction.

### Clause 7-1

The semiconductor device according to Clause 7, further comprising a connecting member electrically joined to the second pad portion and the semiconductor element.

### Clause 7-2

The semiconductor device according to Clause 7, wherein the second pad portion is electrically joined to the semiconductor element.

### Clause 8

The semiconductor device according to Clause 7, wherein the first section penetrates the third resin surface and is spaced apart from the second resin surface in the thickness direction, and
the fourth section penetrates the fourth resin surface and is spaced apart from the second resin surface in the thickness direction.

### Clause 8-1

The semiconductor device according to Clause 8, wherein the second section extends outward from the third section in a second direction orthogonal to the thickness direction and the first direction.

### Clause 8-2

The semiconductor device according to Clause 8, wherein the second section extends from the third section toward the second side in the first direction.

### Clause 9

The semiconductor device according to Clause 8, wherein the second section and the fifth section are located on the second side in the thickness direction with respect to the first resin surface.

### Clause 10

The semiconductor device according to Clause 8 or 9, wherein the second pad portion includes a second-lead obverse surface facing the first side in the thickness direction, and
a surface of the first section on the first side in the thickness direction, the first-lead obverse surface, a surface of the fourth section on the first side in the thickness direction, and the second-lead obverse surface are at a same position in the thickness direction.

### Clause 10-1

The semiconductor device according to Clause 8 or 9, wherein the first-lead reverse surface includes a portion located on the first side in the first direction with respect to the third resin surface as viewed in the thickness direction.

### Clause 11

The semiconductor device according to Clause 7, wherein the third section and the sixth section extend in the thickness direction within the sealing resin, and
the second section and the fifth section are exposed from the first resin surface.

### Clause 11-1

The semiconductor device according to Clause 11, wherein the sealing resin includes a recess recessed from the first resin surface in the thickness direction at a location between the second section and the fifth section in the first direction.

### Clause 12

The semiconductor device according to any one of Clauses 1 to 11, wherein the die pad portion has a first length in the thickness direction and the first section has a second length in the thickness direction, the first length being at least six times and at most ten times the second length.

### Clause 12-1

The semiconductor device according to any one of Clauses 1 to 12, wherein the sealing resin includes a groove recessed from the second resin surface in the thickness direction.

### Clause 12-2

The semiconductor device according to any one of Clauses 1 to 12, wherein the sealing resin includes a protrusion protruding from the second resin surface in the thickness direction.

### Clause 13

A method for manufacturing a semiconductor device, the method comprising:
a step of forming a lead frame having a first terminal portion;
a step of joining a die pad portion to the first terminal portion;
a step of joining a semiconductor element to the die pad portion;
a step of forming a sealing resin covering the semiconductor element; and
a step of cutting the lead frame.

### Clause 14

The method according to Clause 13, wherein the die pad portion includes an engaging portion,
the first terminal portion includes an engaging hole for engagement with the engaging portion, and
the step of joining includes swaging the die pad portion to the first terminal portion.

### Clause 15

The method according to Clause 13, the step of joining includes solid-phase welding by applying vibration in a direction parallel to contact surfaces of the first terminal portion and the die pad portion under pressure applied to the first terminal portion and the die pad portion.

### REFERENCE NUMERALS

A10, A11, A12, A13, A14, A15, A16, A17, A18, A20, A30, A40, A50, A60, A61, A62: Semiconductor device
10: Conductive member 11: First lead
12: Second lead 13: Third lead
14: Fourth lead 20: Semiconductor element
29: Bonding layer 31, 32, 33: Connecting member
40: Sealing resin 41: First resin surface
42: Second resin surface 43: Third resin surface
44: Fourth resin surface 45: Fifth resin surface
46: Sixth resin surface 47: Recess
48: Protrusion 49: Groove
91: Heat sink 92: Circuit board
99: Lead frame 111: Die pad portion
112: First terminal portion 115: Bonding layer
121: Second pad portion 122: Second terminal portion
131: Third pad portion 132: Third terminal portion
141: Fourth pad portion 142: Fourth terminal portion
201: First electrode 202: Second electrode
203: Third electrode 205: Semiconductor layer
411: Recessed region 919: Sheet material
921: Solder 1111: First-lead obverse surface
1112: First-lead reverse surface 1113: First-lead side surface
1114: First intermediate surface 1115: Engaging portion
1121: First section 1122: Second section
1123: Third section 1125: Engaging hole
1126: Boundary surface 1127: Ridge
1211: Second-lead obverse surface 1212: Second-lead reverse surface
1221: Fourth section 1222: Fifth section
1223: Sixth section 1311: Third-lead obverse surface
1312: Third-lead reverse surface 1321: Seventh section
1322: Eighth section 1323: Ninth section
1411: Fourth-lead obverse surface 1412: Fourth-lead reverse surface
1421: Tenth section 1422: Eleventh section
1423: Twelfth section

1. A semiconductor device comprising:
a semiconductor element;
a first lead including a die pad portion and a first terminal portion, the die pad portion including a first-lead obverse surface facing a first side in a thickness direction and on which the semiconductor element is mounted, a first-lead reverse surface facing a second side in the thickness direction, and a first-lead side surface facing a first side in a first direction orthogonal to the thickness direction; and
a sealing resin including a first resin surface facing the first side in the thickness direction and a second resin surface facing the second side in the thickness direction, the sealing resin covering a portion of the die pad portion,
wherein the first-lead reverse surface is exposed from the second resin surface, and
the first terminal portion includes a first section joined to the die pad portion, a second section located on the first side in the thickness direction with respect to the first section and used for mounting, and a third section between the first section and the second section.

2. The semiconductor device according to claim 1, wherein the first section is joined to the first-lead obverse surface.

3. The semiconductor device according to claim 1, wherein the first section is joined to the first-lead side surface.

4. The semiconductor device according to claim 1, wherein the die pad portion further includes an engaging portion,
the first section includes an engaging hole for engagement with the engaging portion, and
the engaging portion is swaged into the engaging hole.

5. The semiconductor device according to claim 1, wherein the die pad portion and the first section are in contact with and integral with each other, and
the first section includes a ridge formed at a boundary with the die pad portion, the ridge being raised in a direction crossing a direction in which a boundary surface between the first section and the die pad portion faces.

6. The semiconductor device according to claim 1, further comprising a bonding layer between the die pad portion and the first section.

7. The semiconductor device according to claim 1, further comprising a second lead spaced apart from the first lead,
wherein the second lead includes a second pad portion and a second terminal portion connected to the second pad portion,
the second terminal portion includes a fourth section connected to the second pad portion, a fifth section located on the first side in the thickness direction with respect to the fourth section and used for mounting, and a sixth section between the fourth section and the fifth section, and
the sealing resin further includes a third resin surface facing the first side in the first direction and a fourth resin surface facing a second side in the first direction.

8. The semiconductor device according to claim 7, wherein the first section penetrates the third resin surface and is spaced apart from the second resin surface in the thickness direction, and
the fourth section penetrates the fourth resin surface and is spaced apart from the second resin surface in the thickness direction.

9. The semiconductor device according to claim 8, wherein the second section and the fifth section are located on the second side in the thickness direction with respect to the first resin surface.

10. The semiconductor device according to claim 8, wherein the second pad portion includes a second-lead obverse surface facing the first side in the thickness direction, and
a surface of the first section on the first side in the thickness direction, the first-lead obverse surface, a surface of the fourth section on the first side in the thickness direction, and the second-lead obverse surface are at a same position in the thickness direction.

11. The semiconductor device according to claim 7, wherein the third section and the sixth section extend in the thickness direction within the sealing resin, and
the second section and the fifth section are exposed from the first resin surface.

12. The semiconductor device according to claim 1, wherein the die pad portion has a first length in the thickness direction and the first section has a second length in the thickness direction, the first length being at least six times and at most ten times the second length.

13. A method for manufacturing a semiconductor device, the method comprising:
a step of forming a lead frame having a first terminal portion;
a step of joining a die pad portion to the first terminal portion;
a step of joining a semiconductor element to the die pad portion;
a step of forming a sealing resin covering the semiconductor element; and
a step of cutting the lead frame.

14. The method according to claim 13, wherein the die pad portion includes an engaging portion,
the first terminal portion includes an engaging hole for engagement with the engaging portion, and
the step of joining includes swaging the die pad portion to the first terminal portion.

15. The method according to claim 13, the step of joining includes solid-state welding by applying vibration in a direction parallel to contact surfaces of the first terminal portion and the die pad portion under pressure applied to the first terminal portion and the die pad portion.
